(19) United States
(12) Patent Application Publication
(10) Pub. No.: US 2023/0383044 A1
(43) Pub. Date: Nov. 30, 2023

(54) COMPOSITION FOR FORMING IMPRINT PATTERN, CURED SUBSTANCE, IMPRINT PATTERN PRODUCING METHOD, DEVICE, AND METHOD FOR MANUFACTURING DEVICE

(71) Applicant: FUJIFILM Corporation, Tokyo (JP)

(72) Inventor: Akihiro HAKAMATA, Haibara-gun (JP)

(73) Assignee: FUJIFILM Corporation, Tokyo (JP)

(21) Appl. No.: 18/360,092

(22) Filed: Jul. 27, 2023

Related U.S. Application Data
(63) Continuation of application No. PCT/JP2022/002488, filed on Jan. 25, 2022.

(30) Foreign Application Priority Data
Jan. 29, 2021 (JP) 2021-013047

(51) Int. Cl. C08F 290/06; C08F 299/00; H01L 21/027; G03F 7/00

(52) U.S. Cl. CPC C08F 290/068; C08F 299/00; H01L 21/0273; G03F 7/0002; B29C 59/02

(57) ABSTRACT

Provided are a composition for forming an imprint pattern, containing a polymerizable compound, a polymerization initiator, and a derivative of the polymerization initiator; a cured substance of the composition for forming an imprint pattern; a device including the cured substance; an imprint pattern producing method using the composition for forming an imprint pattern; and a method for manufacturing a device, including the imprint pattern producing method.

### CROSS-REFERENCE TO RELATED APPLICATIONS

This application is a Continuation of PCT International Application No. PCT/JP2022/002488 filed on Jan. 25, 2022, which claims priority under 35 U.S.C. § 119(a) to Japanese Patent Application No. 2021-013047 filed on Jan. 29, 2021. Each of the above application(s) is hereby expressly incorporated by reference, in its entirety, into the present application.

### BACKGROUND OF THE INVENTION

### 1. Field of the Invention

The present invention relates to a composition for forming an imprint pattern, a cured substance, an imprint pattern producing method, a device, and a method for manufacturing a device.

### 2. Description of the Related Art

An imprinting method is a technique in which a fine pattern is transferred to a material by pressing a metal mold (generally also called a mold or a stamper) on which a pattern is formed. The imprinting method enables simple and precise production of a fine pattern, and thus is expected to be applied in various fields, such as a precision processing field for semiconductor integrated circuits, in recent years. In particular, a nanoimprint technique for forming a fine pattern of a nano-order level is attracting attention.

JP2020-002231A discloses a photocurable composition containing a polymerizable compound (A) having an alkoxysilyl group in a molecule and a polymerization inhibitor (B), in which the polymerization inhibitor (B) is at least one selected from the group consisting of a compound (B1) in which a radical scavenging group is a benzoquinone group, a compound (B2) in which a radical scavenging group is a sterically hindered phenolic hydroxyl group, and a compound (B3) in which a radical scavenging group is a group containing a sterically hindered nitrogen.

WO2006/121162A discloses a curable composition for imprint, containing a polymerizable compound, a photopolymerization initiator, and a mold release agent, in which the polymerizable compound is a light-transmitting polymerizable compound having a maximum value of the following light absorption coefficient A of 1.8 L/(g cm) or lower and having a weight-average molecular weight of 800 or more, the polymerizable compound is contained in an amount of 50% by mass or greater of the total solid content of the composition, the photopolymerization initiator has a maximum value of the following light absorption coefficient B of 5,000 L/(mol·cm) or greater, the photopolymerization initiator is contained in an amount of 0.5% to 8.0% by mass with respect to the total solid content of the composition, and a content of the mold release agent is 0.1% by mass or greater and lower than 1.0% by mass with respect to the total solid content of the composition; light absorption coefficient A: molar absorption coefficient per unit mass in a wavelength range of 250 to 400 nm in an acetonitrile solution; light absorption coefficient B: molar absorption coefficient in a wavelength range of 250 to 400 nm in an acetonitrile solution.

### SUMMARY OF THE INVENTION

As the imprinting method, methods called a thermal imprinting method and a curable imprinting method have been proposed depending on a transfer method. In the thermal imprinting method, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. In this method, various materials can be selected, but there are problems in that it is difficult to form a fine pattern, such as the need for high pressure during pressing and the deterioration of dimensional accuracy due to heat contraction.

On the other hand, in the curable imprinting method, for example, a curable film formed of the composition for forming an imprint pattern is photocured or thermally cured while the mold is pressed against the curable film, and then the mold is released. Since it is imprinted on an uncured substance, it is possible to omit part or all of high-pressure addition and high-temperature heating, and it is possible to easily produce a fine pattern. Moreover, since a dimensional change before and after curing is small, there is also an advantage that a fine pattern can be formed with high accuracy.

Recently, new developments such as a nanocasting method in which the advantages of both the thermal imprinting method and the curable imprinting method are combined, and a reversal imprinting method for producing a three-dimensional laminated structure have also been reported.

In the curable imprinting method, a composition for forming an imprint pattern is applied onto a support (which is subjected to an adhesion treatment as necessary), dried as necessary to form a curable film, and then pressed against a mold made of a light-transmitting material such as quartz. The curable composition for imprint is cured by light irradiation, heating, or the like in a state where the mold is pressed, and then the mold is released to produce a cured substance to which a desired pattern is transferred.

Examples of a method of applying the curable composition for imprint onto the support include a spin coating method and an ink jet method. In particular, the spin coating method has an advantage that it is an application method having excellent productivity from the viewpoint of high throughput.

In addition, a method of performing nanofabrication using a transferred imprint pattern as a mask is called nanoimprint lithography (NIL), and has been developed as a next-generation lithography technology to replace the current ArF liquid immersion process. Therefore, same as EUV resist, the composition for forming an imprint pattern used in NIL is required to be capable of resolving an ultrafine pattern of 20 nm or lower and to have high etching resistance as a mask for nanofabrication of an object to be processed. Specific examples of the curable composition for imprint, which is intended to be used as the mask, include JP5426814B, JP2015-009171A, JP2015-185798A, JP2015-070145A, and JP2015-128134A.

In such an imprinting method, in a case where time elapses after forming the curable film from the composition for forming an imprint pattern, defects may occur in the curable film, such as generation of foreign substance in the curable film.

An object of the present invention is to provide a composition for forming an imprint pattern, in which defects are suppressed even in a case where time elapses after forming a curable film, a cured substance of the composition for forming an imprint pattern, a device including the cured substance, an imprint pattern producing method using the composition for forming an imprint pattern, and a method for manufacturing a device including the imprint pattern producing method.

Typical embodiments of the present invention are shown below.

<1> A composition for forming an imprint pattern, comprising:
a polymerizable compound;
a polymerization initiator; and
a derivative of the polymerization initiator.

<2> The composition for forming an imprint pattern according to <1>, in which a content of the derivative is 1 to 10,000 parts by mass in a case where a content of the polymerization initiator is set to 100 parts by mass.

<3> The composition for forming an imprint pattern according to <1> or <2>,
in which a total content of the polymerization initiator and the derivative is 0.1 to 10.0 parts by mass in a case where a total solid content of the composition for forming an imprint pattern is set to 100 parts by mass.

<4> The composition for forming an imprint pattern according to any one of <1> to <3>,
in which the polymerization initiator is a photopolymerization initiator.

<5> The composition for forming an imprint pattern according to any one of <1> to <4>,
in which both the polymerization initiator and the derivative are acylphosphine oxide-based polymerization initiators or alkylphenone-based polymerization initiators.

<6> The composition for forming an imprint pattern according to any one of <1> to <5>,
in which one of the polymerization initiator or the derivative is diphenyl(2,4,6-trimethylbenzoyl)phosphine oxide and the other is ethyl phenyl(2,4,6-trimethylbenzoyl)phosphinate.

<7> The composition for forming an imprint pattern according to any one of <1> to <5>,
in which one of the polymerization initiator or the derivative is 2-benzyl-2-(dimethylamino)-4′-morpholinobutyrophenone and the other is 2-(dimethylamino)-2-(4-methylbenzyl)-1-(4-morpholinophenyl)butan-1-one.

<8> The composition for forming an imprint pattern according to any one of <1> to <5>,
in which one of the polymerization initiator or the derivative is 2-hydroxy-2-methylpropiophenone and the other is 1-hydroxycyclohexyl phenyl ketone.

<9> A composition for forming an imprint pattern, comprising:
a polymerizable compound; and
a polymerization initiator,
in which the polymerization initiator includes two or more kinds of oxime compounds, two or more kinds of acylphosphine compounds, or two or more kinds of alkylphenone compounds.

<10> The composition for forming an imprint pattern according to any one of <1> to <9>, further comprising:
a mold release agent.

<11> The composition for forming an imprint pattern according to any one of <1> to <10>, further comprising:
a solvent,
in which a content of the solvent is 90.0% to 99.0% by mass with respect to a total mass of the composition for forming an imprint pattern.

<12> A cured substance obtained by curing the composition for forming an imprint pattern according to any one of <1> to <11>.

<13> An imprint pattern producing method comprising:
an applying step of applying the composition for forming an imprint pattern according to any one of <1> to <11> onto a member to be applied, which is selected from the group consisting of a support and a mold;
a contact step of contacting a member which is not selected as the member to be applied from the group consisting of the support and the mold with the composition for forming an imprint pattern as a contact member;
a curing step of forming the composition for forming an imprint pattern into a cured substance; and
a peeling step of peeling off the mold from the cured substance.

<14> The imprint pattern producing method according to <13>,
in which the support is a member including a closely adhesive layer on a surface on a side to which the composition for forming an imprint pattern is applied.

<15> A method for manufacturing a device, comprising:
the imprint pattern producing method according to <13> or <14>.

<16> A device comprising:
the cured substance according to <12>.

According to the present invention, there are provided a composition for forming an imprint pattern, in which defects are suppressed even in a case where time elapses after forming a curable film, a cured substance of the composition for forming an imprint pattern, a device including the cured substance, an imprint pattern producing method using the composition for forming an imprint pattern, and a method for manufacturing a device including the imprint pattern producing method.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step can be achieved.

In the present specification, with regard to a group (atomic group), in a case where the group (atomic group) is described without specifying whether the group (atomic group) is substituted or unsubstituted, the description means that the group (atomic group) includes both a group (atomic group) having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group).

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than a solvent, and a content (concentration) of the solid content in the composition is represented by the mass percentage of the components other than the solvent with respect to the total mass of the composition, unless otherwise specified.

In the present specification, a temperature is 23° C., an atmospheric pressure is 101,325 Pa (1 atm), and a relative humidity is 50% RH, unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified.

The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a support is referred to as “upward” or there is a photosensitive layer, a direction from the support to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 m.

(Composition for Forming Imprint Pattern)

In a first aspect, the composition for forming an imprint pattern according to the present invention contains a polymerizable compound, a polymerization initiator, and a derivative of the polymerization initiator.

In a second aspect, the composition for forming an imprint pattern according to the present invention contains a polymerizable compound and a polymerization initiator, in which the polymerization initiator includes two or more kinds of oxime compounds, two or more kinds of acylphosphine compounds, or two or more kinds of alkylphenone compounds.

Hereinafter, the composition for forming an imprint pattern according to the first aspect of the present invention is also referred to as a first composition for forming an imprint pattern, and the composition for forming an imprint pattern according to the second aspect of the present invention is also referred to as a second composition for forming an imprint pattern.

In addition, hereinafter, a case of being simply described as “composition for forming an imprint pattern according to the embodiment of the present invention” includes both the above-described first composition for forming an imprint pattern and the above-described second composition for forming an imprint pattern.

With the composition for forming an imprint pattern according to the embodiment of the present invention, defects are suppressed even in a case where time elapses after forming a curable film.

The mechanism for obtaining the above-described effect is not clear, but is presumed as follows.

In the related art, various studies have been made on a composition for forming an imprint pattern, which contains a polymerizable compound and a polymerization initiator.

As a result of intensive studies, the present inventors have found that, in the composition for forming an imprint pattern containing the polymerizable compound and the polymerization initiator, in a case where time elapses (for example, 24 hours) after forming a curable film, defects may occur, such as generation of foreign substance in the curable film.

It is presumed that this is because the polymerization initiator is precipitated in the curable film.

As a result of intensive studies, the present inventors have found that, in an aspect of containing a polymerization initiator and a derivative of the polymerization initiator or in an aspect in which a polymerization initiator contains two or more kinds of oxime compounds, two or more kinds of acylphosphine compounds, or two or more kinds of alkylphenone compounds, the above-described defects are suppressed.

It is presumed that this is because, according to the above-described aspects, crystallinity of the polymerization initiator is reduced, and the precipitation in the curable film is suppressed.

Hereinafter, the composition for forming an imprint pattern according to the embodiment of the present invention will be described in detail.

<Polymerizable Compound>

The composition for forming an imprint pattern according to the embodiment of the present invention contains a polymerizable compound.

In the first composition for forming an imprint pattern and the second composition for forming an imprint pattern, preferred aspects of the polymerizable compound are the same.

In addition, hereinafter, unless otherwise specified, preferred aspects of components contained in the first composition for forming an imprint pattern and the second composition for forming an imprint pattern are the same.

In the composition for forming an imprint pattern according to the embodiment of the present invention, it is preferable that, among components contained in the composition for forming an imprint pattern according to the embodiment of the present invention, other than a solvent, a component with the highest content is the polymerizable compound. The polymerizable compound may have one polymerizable group or two or more polymerizable groups in one molecule. At least one kind of polymerizable compounds contained in the composition for forming an imprint pattern preferably has two to five polymerizable groups, more preferably has two to four polymerizable groups, still more preferably has two or three polymerizable groups, and even more preferably has three polymerizable groups, in one molecule.

The type of the polymerizable group included in the polymerizable compound is not particularly specified, and examples thereof include a group having an ethylenically unsaturated group and a cyclic ether group (an epoxy group, a glycidyl group, and an oxetanyl group). Among them, a group having an ethylenically unsaturated group is preferable. Examples of the group having an ethylenically unsaturated group include a (meth)acryloyl group, a (meth)acryloyloxy group, a (meth)acryloylamino group, a vinyl group, a vinyloxy group, an allyl group, and a vinylphenyl group. Among them, a (meth)acryloyl group or a (meth)acryloyloxy group is more preferable, and an acryloyl group or an acryloyloxy group is still more preferable.

At least one kind of polymerizable compounds contained in the composition for forming an imprint pattern preferably has a cyclic structure. Examples of this cyclic structure include an aliphatic hydrocarbon ring Cf and an aromatic hydrocarbon ring Cr. Among these, the polymerizable compound preferably has the aromatic hydrocarbon ring Cr and more preferably has a benzene ring.

A molecular weight of the polymerizable compound is preferably 100 to 900.

At least one kind of the above-described polymerizable compounds is preferably represented by Formula (I-1).

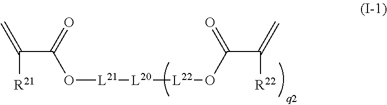

L²⁰ is a (1+q2)-valent linking group, and examples thereof include a linking group having a cyclic structure. Examples of the cyclic structure include examples of the ring Cf, the ring Cr, the ring Cn, the ring Co, and the ring Cs.

R²¹ and R²² each independently represent a hydrogen atom or a methyl group.

L²¹ and L²² each independently represent a single bond or the linking group L. L²⁰ and L²¹ or L²² may be bonded to each other through or without the linking group L to form a ring. L²⁰, L²¹, and L²² may have the substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, and still more preferably 0 or 1.

[High-Molecular-Weight Polymerizable Compound]

Moreover, the composition for forming an imprint pattern may contain, as the polymerizable compound, a polymerizable compound having a weight-average molecular weight of 800 or more (hereinafter, also referred to as a “high-molecular-weight polymerizable compound”).

Examples of the high-molecular-weight polymerizable compound include a compound (silicon-containing compound) containing a silicon atom (Si), a compound (ring-containing compound) containing a cyclic structure, and a dendrimer-type compound, and a silicon-containing compound or a ring-containing compound is preferable and a silicon-containing compound is more preferable.

A weight-average molecular weight of the high-molecular-weight polymerizable compound is 800 or more, preferably 1,000 or more, more preferably 1,500 or more, and still more preferably more than 2,000. The upper limit of the weight-average molecular weight is not particularly specified, but for example, 100,000 or less is preferable, 50,000 or less is more preferable, 10,000 or less is still more preferable, 8,000 or less is even more preferable, 5,000 or less is even still more preferable, 3,500 or less is particularly preferable, and 3,000 or less is more particularly preferable. By setting the molecular weight to the above-described lower limit value or more, a volatility of the compound is suppressed, and characteristics of the composition or a coating film are stabilized. Moreover, good viscosity for maintaining a morphology of the coating film can be ensured. Further, it is possible to realize good releasability of the film by complementing the effect of suppressing a mold release agent to a small amount. By setting the molecular weight to the above-described upper limit value or lower, it is easy to secure a low viscosity (fluidity) required for pattern filling, which is preferable.

—Silicon-Containing Compound—

Examples of the silicon-containing compound include a compound having a silicone skeleton. Specific examples thereof include a compound having at least one of a D-unit siloxane structure represented by Formula (S1) or a T-unit siloxane structure represented by Formula (S2).

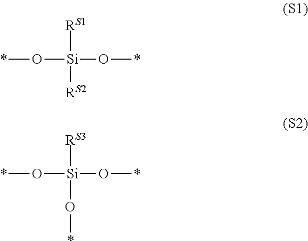

In Formula (S1) or Formula (S2), R^{S1} to R^{S3} each independently represent a hydrogen atom or a monovalent substituent, and *'s each independently represent a bonding site with other structures.

R^{S1} to R^{S3} are each independently preferably a monovalent substituent.

As the above-described monovalent substituent, an aromatic hydrocarbon group (preferably having 6 to 22 carbon atoms, more preferably having 6 to 18 carbon atoms, and still more preferably having 6 to 10 carbon atoms) or an aliphatic hydrocarbon group (preferably having 1 to 24 carbon atoms, more preferably having 1 to 12 carbon atoms, and still more preferably having 1 to 6 carbon atoms) is preferable, and among them, a cyclic or chain (linear or branched) alkyl group (preferably having 1 to 12 carbon atoms, more preferably having 1 to 6 carbon atoms, and still more preferably having 1 to 3 carbon atoms) or a group including a polymerizable group is preferable.

Specific examples of a structure of the silicon-containing compound include the following examples of Formulae (s-1) to (s-9) in terms of partial structure. Q in the formulae is a group including the above-described polymerizable group. A plurality of these structures may be present in the compound, or may be present in combination.

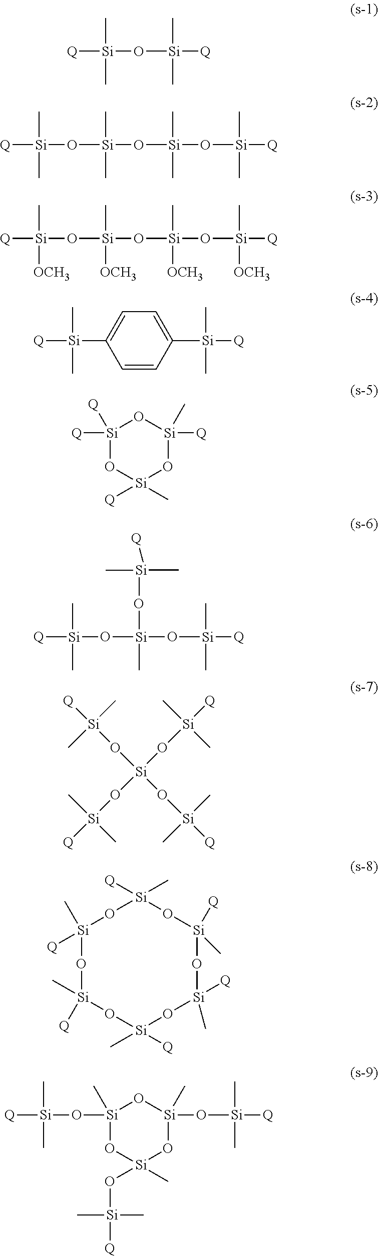

The silicon-containing compound is preferably a reactant of a silicone resin and a compound having a polymerizable group.

As the above-described silicone resin, a reactive silicone resin is preferable.

Examples of the reactive silicone resin include a modified silicone resin having the above-described silicone skeleton, and for example, a monoamine-modified silicone resin, a diamine-modified silicone resin, a special amino-modified silicone resin, an epoxy-modified silicone resin, an alicyclic epoxy-modified silicone resin, a carbinol-modified silicone resin, a mercapto-modified silicone resin, a carboxy-modified silicone resin, a hydrogen-modified silicone resin, an amino-polyether-modified silicone resin, an epoxy-polyether-modified silicone resin, an epoxy-aralkyl-modified silicone resin, and the like can be mentioned.

As the above-described compound having a polymerizable group, a compound having a polymerizable group and a group capable of reacting with an alkoxysilyl group or a silanol group is preferable, and a compound having a polymerizable group and a hydroxy group is more preferable.

Moreover, in a case where the above-described modified silicone resin is used as the silicone resin, as the above-described compound having a polymerizable group, a compound having a polymerizable group and a group which reacts with an amino group, an epoxy group, a mercapto group, a carboxy group, and the like, which are included in the above-described modified silicone resin, may be used.

A preferred aspect of the polymerizable group in the above-described compound having a polymerizable group is the same as the preferred aspect of the polymerizable group in the above-described polymerizable compound.

As the above-described compound having a polymerizable group, among them, hydroxyalkyl (meth)acrylate is preferable, and 2-hydroxyethyl (meth)acrylate is more preferable.

More specifically, a reactant of a compound having a polymerizable group and a group (for example, a hydroxy group) capable of reacting with an alkoxysilyl group or a silanol group and a silicone resin having an alkoxysilyl group or a silanol group is preferable.

—Ring-Containing Compound—

Examples of a cyclic structure of the compound (ring-containing compound) containing a ring include an aromatic ring and an alicyclic ring. Examples of the aromatic ring include an aromatic hydrocarbon ring and an aromatic heterocyclic ring.

The aromatic hydrocarbon ring preferably has 6 to 22 carbon atoms, more preferably has 6 to 18 carbon atoms, and still more preferably has 6 to 10 carbon atoms. Specific examples of the aromatic hydrocarbon ring include a benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring. Among them, a benzene ring or a naphthalene ring is preferable, and a benzene ring is more preferable. The aromatic ring may have a structure in which a plurality of rings is linked to each other, and examples thereof include a biphenyl structure and a diphenylalkane structure (for example, 2,2-diphenylpropane) (the aromatic hydrocarbon ring specified here is referred to as aCy).

The aromatic heterocyclic ring preferably has 1 to 12 carbon atoms, more preferably has 1 to 6 carbon atoms, and still more preferably has 1 to 5 carbon atoms. Specific examples thereof include a thiophene ring, a furan ring, a dibenzofuran ring, a pyrrole ring, an imidazole ring, a benzimidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, a pyridazine ring, an isoindole ring, an indole ring, an indazole ring, a purine ring, a quinolidine ring, an isoquinoline ring, a quinoline ring, a phthalazine ring, a naphthylidine ring, a quinoxaline ring, a quinazoline ring, a cinnoline ring, a carbazole ring, an acridine ring, a phenazine ring, a phenothiazine ring, a phenoxathiin ring, and a phenoxazine ring (the aromatic heterocyclic ring specified here is referred to as hCy).

The alicyclic ring preferably has 3 to 22 carbon atoms, more preferably has 4 to 18 carbon atoms, and still more preferably has 6 to 10 carbon atoms. Specific examples of the aliphatic hydrocarbon ring include a cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydrodicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring. Examples of the aliphatic hetero ring include a pyrrolidine ring, an imidazolidine ring, a piperidine ring, a piperazine ring, a morpholine ring, an oxirane ring, an oxetane ring, an oxolane ring, an oxane ring, and a dioxane ring (the alicyclic ring specified here is referred to as fCy).

In the present invention, in a case where the high-molecular-weight polymerizable compound is a ring-containing compound, a compound containing an aromatic hydrocarbon ring is preferable, and a compound having a benzene ring is more preferable. Examples thereof include a compound having a structure represented by Formula (C-1).

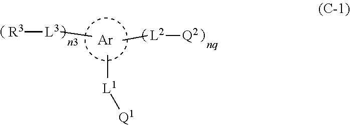

In the formula, Ar represents the above-described aromatic hydrocarbon ring or aromatic heterocyclic ring.

L¹ and L² are each independently a single bond or a linking group. Examples of the linking group include an oxygen atom (oxy group), a carbonyl group, an amino group, an alkylene group (preferably having 1 to 12 carbon atoms, more preferably having 1 to 6 carbon atoms, and still more preferably 1 to 3 carbon atoms), and a group of a combination of these groups. Among them, a (poly)alkyleneoxy group is preferable. The (poly)alkyleneoxy group may be a group having one alkyleneoxy group or a group in which a plurality of alkyleneoxy groups is repeatedly linked. Moreover, an order of the alkylene group and the oxy group is not limited. The repetition number of the alkyleneoxy group is preferably 1 to 24, more preferably 1 to 12, and still more preferably 1 to 6. Moreover, the (poly)alkyleneoxy group may be intervened with an alkylene group (preferably having 1 to 24 carbon atoms, more preferably having 1 to 12 carbon atoms, and still more preferably having 1 to 6 carbon atoms) in relation to linking with the ring Ar which is a mother nucleus or with the polymerizable group Q. Therefore, (poly)alkyleneoxy=alkylene group may be used.

R³ is an optional substituent, and examples thereof include an alkyl group (preferably having 1 to 12 carbon atoms, more preferably having 1 to 6 carbon atoms, and still more preferably having 1 to 3 carbon atoms), an alkenyl group (preferably having 2 to 12 carbon atoms, more preferably having 2 to 6 carbon atoms, and still more preferably having 2 or 3 carbon atoms), an aryl group (preferably having 6 to 22 carbon atoms, more preferably having 6 to 18 carbon atoms, and still more preferably having 6 to 10 carbon atoms), an arylalkyl group (preferably having 7 to 23 carbon atoms, more preferably having 7 to 19 carbon atoms, and still more preferably having 7 to 11 carbon atoms), a hydroxy group, a carboxy group, an alkoxy group (preferably having 1 to 24 carbon atoms, more preferably having 1 to 12 carbon atoms, and still more preferably having 1 to 6 carbon atoms), an acyl group (preferably having 2 to 12 carbon atoms, more preferably having 2 to 6 carbon atoms, and still more preferably having 2 or 3 carbon atoms; also preferably an alkylcarbonyl group), and an aryloyl group (preferably having 7 to 23 carbon atoms, more preferably having 7 to 19 carbon atoms, and still more preferably having 7 to 11 carbon atoms).

L³ is a single bond or a linking group. Examples of the linking group include the examples of L¹ and L² described above.

n3 is preferably 3 or less, more preferably 2 or less, still more preferably 1 or less, and particularly preferably 0.

Q¹ and Q² are each independently a polymerizable group, and the example of the above-described polymerizable group is preferable.

In the ring-containing compound, in a case where the number of side chains having a polymerizable group is increased, it is possible to form a strong crosslinking structure during curing, and the resolution tends to be improved. From this viewpoint, nq is 1 or more, preferably 2 or more. The upper limit thereof is preferably 6 or less, more preferably 4 or less, and still more preferably 3 or less.

Similarly, from the viewpoint of easily forming a uniform crosslinking structure, in a case where a group including a polymerizable group or a substituent is introduced into the cyclic structure, it is preferable that the substituents are arranged in series.

—Dendrimer-Type Compound—

The high-molecular-weight polymerizable compound may be a dendrimer-type compound. The dendrimer means a dendritic polymer having a structure which branches regularly from a center. The dendrimer is composed of a central molecule (stem) called as a core and a side chain portion (branch) called as a dendron. As a whole, a fan-shaped compound is common, but a dendrimer in which dendrons are spread in a semicircular or circular shape may be used. A group having a polymerizable group can be introduced into a dendron portion (for example, a terminal portion away from the core) of the dendrimer to obtain the polymerizable compound. In a case where a (meth)acryloyl group is used as the polymerizable group to be introduced, a dendrimer-type polyfunctional (meth)acrylate can be obtained.

For the dendrimer-type compound, for example, matters described in JP5512970B can be referred to, the description of which is incorporated in the present specification.

—Polymerizable Group Equivalent—

A polymerizable group equivalent of the high-molecular-weight polymerizable compound is preferably 130 or more, more preferably 150 or more, still more preferably 160 or more, even more preferably 190 or more, and even still more preferably 240 or more. The upper limit value of the polymerizable group equivalent is preferably 2,500 or less, more preferably 1,800 or less, still more preferably 1,000 or less, even more preferably 500 or less, and even still more preferably 350 or less, and may be 300 or less.

The polymerizable group equivalent is calculated by the following expression.

(Polymerizable group equivalent)=(Number-average molecular weight of polymerizable compound)/(Number of polymerizable groups in polymerizable compound)

In a case where the polymerizable group equivalent of the high-molecular-weight polymerizable compound is the above-described lower limit value or more, it is considered that the elastic modulus during curing is in an appropriate range and the releasability is excellent. On the other hand, in a case where the polymerizable group equivalent is the above-described upper limit value or less, it is considered that a crosslinking density of the cured substance pattern is in an appropriate range and the resolution of the transfer pattern is excellent.

In a case of the silicon-containing compound, the number of polymerizable groups in the high-molecular-weight polymerizable compound is preferably 2 or more, more preferably 3 or more, and still more preferably 4 or more in one molecule. The upper limit thereof is preferably 50 or less, more preferably 40 or less, still more preferably 30 or less, and even more preferably 20 or less.

In a case of the ring-containing compound, it is preferable to be 2 or more in one molecule. The upper limit thereof is preferably 4 or less and more preferably 3 or less.

Alternatively, in a case of the dendrimer-type compound, it is preferable to be 5 or more, more preferably 10 or more, and still more preferably 20 or more in one molecule. The upper limit thereof is preferably 1,000 or less, more preferably 500 or less, and still more preferably 200 or less.

—Viscosity—

A viscosity of the high-molecular-weight polymerizable compound at 23° C. is preferably 100 mPa·s or greater, more preferably 120 mPa·s or greater, and still more preferably 150 mPa·s or greater. The upper limit value of the above-described viscosity is preferably 2,000 mPa·s or lower, more preferably 1,500 mPa·s or lower, and still more preferably 1,200 mPa·s or lower.

Unless otherwise specified, the viscosity in the present specification is a value measured with an E-type rotational viscometer RE85L manufactured by TOKI SANGYO CO., LTD. and a standard cone rotor (1° 34′×R24) in a state where a temperature of a sample cup is adjusted to 23° C. Other details regarding the measurement are in accordance with JIS Z 8803:2011. Two samples are produced for one level and are respectively measured three times. An arithmetic mean value of a total of six times is adopted as an evaluation value.

Examples of the polymerizable compound include compounds used in the following Examples, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A, but the present invention is not construed as being limited thereto.

With respect to the total solid content of the composition for forming an imprint pattern, a content of the polymerizable compound is preferably 30% by mass or greater, more preferably 45% by mass or greater, still more preferably 50% by mass or greater, and even more preferably 55% by mass or greater, and may be 60% by mass or greater or further 70% by mass or greater. In addition, the upper limit value thereof is preferably lower than 99% by mass and more preferably 98% by mass or lower, and can also be 97% by mass or lower.

It is preferable that a boiling point of the polymerizable compound is set and designed on formulation in relation to a curable main agent contained in a composition for forming a closely adhesive layer, which will be described later. The boiling point of the polymerizable compound is preferably 500° C. or lower, more preferably 450° C. or lower, and still more preferably 400° C. or lower. The lower limit value thereof is preferably 200° C. or higher, more preferably 220° C. or higher, and still more preferably 240° C. or higher.

<Polymerization Initiator>

The composition for forming an imprint pattern according to the embodiment of the present invention contains a polymerization initiator.

The first composition for forming an imprint pattern contains a polymerization initiator and a derivative of the polymerization initiator.

In the second composition for forming an imprint pattern, the polymerization initiator includes two or more kinds of oxime compounds, two or more kinds of acylphosphine compounds, or two or more kinds of alkylphenone compounds.

The polymerization initiator contained in the composition for forming an imprint pattern according to the embodiment of the present invention may be a photopolymerization initiator or a thermal polymerization initiator, a photopolymerization initiator is preferable.

The photopolymerization initiator contained in the composition for forming an imprint pattern according to the embodiment of the present invention can be used without any particular limitation as long as it is a compound that generates active species for polymerizing the above-described polymerizable compound by light irradiation.

The thermal polymerization initiator contained in the composition for forming an imprint pattern according to the embodiment of the present invention can be used without any particular limitation as long as it is a compound that generates active species for polymerizing the above-described polymerizable compound by heating.

As the polymerization initiator, a radical polymerization initiator or a cationic polymerization initiator is preferable, and a radical polymerization initiator is more preferable.

In addition, in the present invention, a plurality of kinds of polymerization initiators may be used in combination.

Hereinafter, first, a polymerization initiator and a derivative of the polymerization initiator, contained in the first composition for forming an imprint pattern, will be described.

Examples of the photoradical polymerization initiator contained in the first composition for forming an imprint pattern include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an α-aminoketone compound such as aminoacetophenone, an α-hydroxyketone compound such as hydroxyacetophenone, an azo-based compound, an azide compound, a metallocene compound, an organic boron compound, and an iron arene complex. For the details thereof, reference can be made to the description in paragraphs 0165 to 0182 of JP2016-027357A and paragraphs 0138 to 0151 of WO2015/199219A, the contents of which are incorporated in the present specification. In addition, examples thereof also include compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, and peroxide initiators described in JP2019-167313A, the contents of which are incorporated herein by reference.

As the thermal radical polymerization initiator, a known thermal radical polymerization initiator can be used without particular limitation, and specific examples thereof include compounds described in paragraphs 0074 to 0118 of JP2008-063554A, the contents of which are incorporated herein by reference.

In addition, among the above-described photopolymerization initiators, those having a function of initiating polymerization by heat can also be added as the thermal polymerization initiator.

In the present invention, it is preferable that both the polymerization initiator and the derivative contained in the first composition for forming an imprint pattern are acylphosphine oxide-based polymerization initiators or alkylphenone-based photopolymerization initiators.

The acylphosphine oxide-based polymerization initiator is not particularly limited, and examples thereof include diphenyl(2,4,6-trimethylbenzoyl)phosphine oxide, ethyl phenyl(2,4,6-trimethylbenzoyl)phosphinate, benzoyl-diphenylphosphine oxide, 2,3,5,6-tetramethylbenzoyl-diphenylphosphine oxide, 3,4-dimethylbenzoyl-diphenylphosphine oxide, bis(2,4,6-trimethylbenzoyl)-phenylphosphine oxide, bis(2,6-dimethoxybenzoyl)-2,4,4-trimethyl-pentylphosphine oxide, and bis(2,6-dimethylbenzoyl)-ethylphosphine oxide. In addition, as a commercially available product thereof, Omnirad 819, Omnirad TPO H, and Omnirad TPO L (all manufactured by IGM Resins B.V.), IRGACURE-819 and IRGACURE-TPO (trade names; both manufactured by BASF SE), or the like can be used.

Examples of the alkylphenone-based polymerization initiator include an α-aminoketone compound such as aminoacetophenone and an α-hydroxyketone compound such as hydroxyacetophenone.

The α-hydroxyketone compound is not particularly limited, and examples thereof include 2-hydroxy-2-methylpropiophenone, 1-hydroxycyclohexyl phenyl ketone, 1-[4-(2-hydroxyethoxy)phenyl]-2-hydroxy-2-methyl-1-propan-1-one, and 2-hydroxy-1-(4-(4-(2-hydroxy-2-methylpropionyl)benzyl)phenyl)-2-methylpropan-1-one. In addition, as a commercially available product thereof, Omnirad 184, Omnirad 1173, Omnirad 500, Omnirad 2959, and Omnirad 127 (all manufactured by IGM Resins B.V.), IRGACURE-184, DAROCUR-1173, IRGACURE-500, IRGACURE-2959, and IRGACURE-127 (all manufactured by BASF SE), or the like can be used.

The α-aminoketone compound is not particularly limited, and examples thereof include 2-benzyl-2-(dimethylamino)-4′-morpholinobutyrophenone, 2-(dimethylamino)-2-(4-methylbenzyl)-1-(4-morpholinophenyl)butan-1-one, and 2-methyl-1-[4-(methylthio)phenyl]-2-morpholinopropan-1-one. In addition, as a commercially available product thereof, IRGACURE-907, IRGACURE-369, IRGACURE-379, and IRGACURE-379EG (all manufactured by BASF SE), or the like can be used.

Moreover, one of aspects represented by the following (1A) to (1C) is also one of the preferred aspects of the present invention.
(1A) one of the above-described polymerization initiator or the above-described derivative is diphenyl(2,4,6-trimethylbenzoyl)phosphine oxide and the other is ethyl phenyl(2,4,6-trimethylbenzoyl)phosphinate.
(1B) one of the above-described polymerization initiator or the above-described derivative is 2-benzyl-2-(dimethylamino)-4′-morpholinobutyrophenone and the other is 2-(dimethylamino)-2-(4-methylbenzyl)-1-(4-morpholinophenyl)butan-1-one.
(1C) one of the above-described polymerization initiator or the above-described derivative is 2-hydroxy-2-methylpropiophenone and the other is 1-hydroxycyclohexyl phenyl ketone.

[Derivative]

In the present invention, it is preferable that the derivative of the polymerization initiator is a compound which has the same partial structure as the polymerization initiator and has a formula weight of the partial structure of 40% by mass or greater with respect to the molecular weight of the polymerization initiator. The formula weight of the above-described partial structure is preferably 60% by mass or greater, more preferably 70% by mass or greater with respect to the molecular weight of the polymerization initiator. In addition, the above-described partial structure is a one-connection structure connected by a covalent bond. That is, in a case where the polymerization initiator and the derivative have two or more identical partial structures in the molecule, only one having the larger formula weight is used in the calculation.

As described above, by using a compound in which a large proportion of the same partial structure occupies is used as the polymerization initiator and the derivative thereof, it is considered that crystallinity of the polymerization initiator can be reduced, and the defects are suppressed even in a case where time elapses in the state of the curable film.

In the present invention, the derivative of the polymerization initiator may be a polymerization initiator or a compound having no polymerization initiating ability. In a case where the derivative is a polymerization initiator (has a polymerization initiating ability), one may be used as the polymerization initiator and the other may be used as the derivative, but one can be determined as the polymerization initiator and the other can be determined as the derivative so that the proportion of the formula weight of the partial structure to the molecular weight of the derivative described above is large.

In addition, in the case where the derivative is a polymerization initiator, it is preferable that one is selected from the group consisting of the halogenated hydrocarbon derivative, the acylphosphine compound, hexaarylbiimidazole, the oxime compound such as an oxime derivative, the organic peroxide, the thio compound, the ketone compound, the aromatic onium salt, the ketoxime ether, the α-aminoketone compound, the α-hydroxyketone compound, the azo-based compound, the azide compound, the metallocene compound, the organic boron compound, and the iron arene complex described above, and the other is a compound of the same type. The compound of the same type means, for example, that one is a halogenated hydrocarbon derivative and the other is a halogenated hydrocarbon derivative having a different structure.

Examples thereof include an aspect in which the polymerization initiator is ethyl phenyl(2,4,6-trimethylbenzoyl)phosphinate and the derivative is diphenyl(2,4,6-trimethylbenzoyl)phosphine oxide.

In this case, with regard to the formula weight (271.28) of the same partial structure as the polymerization initiator in the derivative, with respect to the molecular weight (316.34) of the polymerization initiator, 271.28/316.34×100=86.1% by mass.

In addition, examples of the case where the derivative does not have the polymerization initiating ability include an aspect in which the polymerization initiator is diphenyl(2,4,6-trimethylbenzoyl)phosphine oxide and the derivative is the following compound Z-1.

Examples of the case where the derivative does not have the polymerization initiating ability also include an aspect in which the polymerization initiator is 2-hydroxy-2-methylpropiophenone and the derivative is the following compound Z-2.

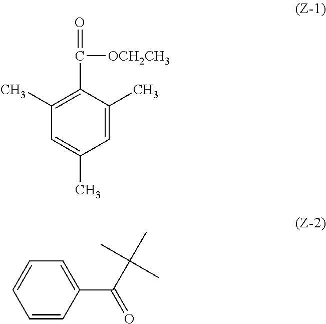

A content of the polymerization initiator in the first composition for forming an imprint pattern is, for example, 0.01% to 15% by mass with respect to the total solid content of the composition, preferably 0.1% to 10% by mass and more preferably 0.2% to 7% by mass. In a case where two or more kinds of the polymerization initiators are used, the total amount thereof is preferably within the above-described range.

In a case where the content of the polymerization initiator is 0.01% by mass or greater, sensitivity (rapid curing properties), resolution, line edge roughness, and coating film strength tend to be improved, which is preferable. On the other hand, in a case where the content of the polymerization initiator is 15% by mass or lower, light transmittance, colorability, storage stability, and the like tend to be improved, which is preferable.

In addition, in a case where the total solid content of the composition for forming an imprint pattern is set to 100 parts by mass, the total content of the above-described polymerization initiator and the above-described derivative is, for example, 0.01 to 15 parts by mass, preferably 0.1 to 10 parts by mass and more preferably 0.2 to 7 parts by mass. In a case where two or more kinds of the polymerization initiators and two or more kinds of the derivatives are used, the total amount of all of them is preferably within the above-described range.

In a case where the content of the polymerization initiator in the first composition for forming an imprint pattern is set to 100 parts by mass, a content of the above-described derivative is preferably 1 to 10,000 parts by mass, more preferably 5 to 2,000 parts by mass, and still more preferably 10 to 1,000 parts by mass.

Hereinafter, a polymerization initiator and a derivative of the polymerization initiator, contained in the second composition for forming an imprint pattern, will be described.

The polymerization initiator in the second composition for forming an imprint pattern includes two or more kinds of oxime compounds, two or more kinds of acylphosphine compounds, or two or more kinds of alkylphenone compounds.

Details of the acylphosphine compound and the alkylphenone compound are as described above with regard to the acylphosphine oxide-based polymerization initiator and the alkylphenone-based polymerization initiator.

The oxime compound is not particularly limited, and examples thereof include a compound having the following structure, 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one.

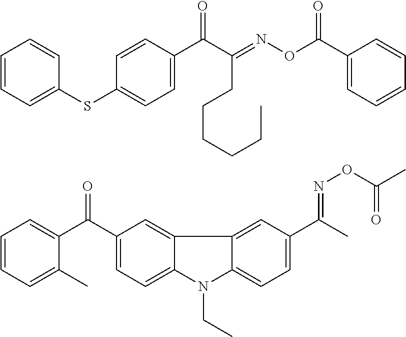 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

As a commercially available product thereof, IRGACURE OXE 01, IRGACURE OXE 02, IRGACURE OXE 03, and IRGACURE OXE 04 (all manufactured by BASF SE), and ADEKA OPTOMER N-1919 (manufactured by ADEKA Corporation; photoradical polymerization initiator 2 described in JP2012-014052A) are also suitably used. In addition, TR-PBG-304 and TR-PBG-305 (manufactured by Changzhou Tronly New Electronic Materials Co., Ltd.) and ADEKA ARKLS NCI-730, NCI-831, and ADEKA ARKLS NCI-930 (manufactured by ADEKA Corporation) can be used. Moreover, DFI-091 (manufactured by DAITO CHEMIX Co., Ltd.) and SpeedCure PDO (manufactured by SARTOMER ARKEMA) can be used.

Moreover, one of aspects represented by the following (2A) to (2C) is also one of the preferred aspects of the present invention.
(2A) the above-described polymerization initiator includes diphenyl(2,4,6-trimethylbenzoyl)phosphine oxide and ethyl phenyl(2,4,6-trimethylbenzoyl)phosphinate.
(2B) the above-described polymerization initiator includes 2-benzyl-2-(dimethylamino)-4′-morpholinobutyrophenone and 2-(dimethylamino)-2-(4-methylbenzyl)-1-(4-morpholinophenyl)butan-1-one
(2C) the above-described polymerization initiator includes 2-hydroxy-2-methylpropiophenone and 1-hydroxycyclohexyl phenyl ketone.

The total content of the polymerization initiators in the second composition for forming an imprint pattern is, for example, 0.01% to 15% by mass with respect to the total solid content of the composition, preferably 0.1% to 10% by mass and more preferably 0.2% to 7% by mass.

In a case where the content of the polymerization initiator is 0.01% by mass or greater, sensitivity (rapid curing properties), resolution, line edge roughness, and coating film strength tend to be improved, which is preferable. On the other hand, in a case where the content of the polymerization initiator is 15% by mass or lower, light transmittance, colorability, storage stability, and the like tend to be improved, which is preferable.

[Mold Release Agent]

The composition for forming an imprint pattern according to the embodiment of the present invention preferably contains a mold release agent.

A content of the mold release agent is preferably 0.1% by mass or greater, more preferably 0.3% by mass or greater, still more preferably 0.5% by mass or greater, and particularly preferably 0.6% by mass or greater with respect to the total solid content of the composition. The upper limit value thereof is preferably lower than 1.0% by mass, more preferably 0.9% by mass or lower, and still more preferably 0.85% by mass or lower.

In a case where the content of the mold release agent is the above-described lower limit value or greater, the releasability is improved, and peeling of the cured film and damage to the mold during mold release can be prevented. Moreover, in a case of being the above-described upper limit value or lower, a pattern strength during curing is not excessively lowered due to the influence of the mold release agent, so that good resolution can be realized.

The mold release agent may be used alone or in combination of a plurality thereof. In a case where a plurality thereof is used, the total amount thereof is within the above-described range.

The type of the mold release agent is not particularly limited, but it is preferable to have a function of segregating at an interface with the mold and effectively promoting mold release from the mold. In the present invention, it is preferable that the mold release agent does not substantially include a fluorine atom and a silicon atom. The expression “not substantially include” means that the total amount of the fluorine atom and the silicon atom is 1% by mass or lower of the mold release agent, preferably 0.5% by mass or lower, more preferably 0.1% by mass or lower, and still more preferably 0.01% by mass or lower. From the viewpoint of achieving high releasability of the film and excellent processing resistance to etching and the like, it is preferable that the mold release agent which does not substantially include a fluorine atom and a silicon atom is used in the curable composition for imprint.

Specifically, the mold release agent used in the present invention is preferably a surfactant. Alternatively, it is preferably an alcohol compound having at least one hydroxy group at a terminal, or a compound ((poly)alkylene glycol compound) having a (poly)alkylene glycol structure in which a hydroxy group is etherified. The surfactant and the (poly)alkylene glycol compound are preferably a non-polymerizable compound not having the polymerizable group. The (poly)alkylene glycol means that an alkylene glycol structure may be one or a plurality of the alkylene glycol structures may be repeatedly linked.

—Surfactant—

As the surfactant which can be used as the mold release agent in the present invention, a nonionic surfactant is preferable.

The nonionic surfactant is a compound having at least one hydrophobic moiety and at least one nonionic hydrophilic moiety. The hydrophobic moiety and the hydrophilic moiety may each be at a terminal of a molecule, or inside. The hydrophobic moiety is composed of, for example, a hydrocarbon group, and the number of carbon atoms in the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxyl group, a phenolic hydroxyl group, an ether group (preferably, a (poly)alkyleneoxy group and a cyclic ether group), an amide group, an imide group, a ureide group, a urethane group, a cyano group, a sulfonamide group, a lactone group, a lactam group, and a cyclocarbonate group. Among them, a compound having an alcoholic hydroxyl group or an ether group (preferably, a (poly)alkyleneoxy group and a cyclic ether group) is more preferable.

—Alcohol Compound and (Poly)Alkylene Glycol Compound—

As described above, examples of a preferred mold release agent used in the curable composition for imprint according to the embodiment of the present invention include an alcohol compound having at least one hydroxy group at a terminal and a (poly)alkylene glycol compound in which a hydroxy group is etherified.

Specifically, the (poly)alkylene glycol compound preferably has an alkyleneoxy group or a polyalkyleneoxy group, and more preferably has a (poly)alkyleneoxy group including an alkylene group having 1 to 6 carbon atoms. Specifically, it is preferable to have a (poly)ethyleneoxy group, a (poly)propyleneoxy group, a (poly)butyleneoxy group, or a mixed structure thereof, it is more preferable to have a (poly)ethyleneoxy group, a (poly)propyleneoxy group, or a mixed structure thereof, and it is still more preferable to have a (poly)propyleneoxy group. The (poly)alkylene glycol compound may be substantially constituted of only a (poly)alkyleneoxy group, except for a substituent at a terminal. Here, the expression “substantially” means that constituent elements other than the (poly)alkyleneoxy group account for 5% by mass or lower and preferably 1% by mass or lower of the entire compound. In particular, it is particularly preferable that the (poly)alkylene glycol compound includes a compound substantially constituted of only the (poly)propyleneoxy group.

The repetition number of alkyleneoxy groups in the (poly)alkylene glycol compound is preferably 3 to 100, more preferably 4 to 50, still more preferably 5 to 30, and even more preferably 6 to 20.

As long as the hydroxy group at the terminal is etherified, the (poly)alkylene glycol compound may have a hydroxy group at the remaining terminal, or may have a terminal hydroxy group in which a hydrogen atom is substituted. As a group in which the hydrogen atom of the terminal hydroxy group may be substituted, an alkyl group (that is, (poly)alkylene glycol alkyl ether) or an acyl group (that is, (poly)alkylene glycol ester) is preferable. A compound having a plurality (preferably, two or three) of (poly)alkylene glycol chains through a linking group can also be preferably used.

Preferred specific examples of the (poly)alkylene glycol compound include polyethylene glycol, polypropylene glycol (for example, manufactured by FUJIFILM Wako Pure Chemical Corporation), mono or dimethyl ether thereof, mono or dibutyl ether, mono or dioctyl ether, mono or dicetyl ether, monostearic acid ester, monooleic acid ester, polyoxyethylene glyceryl ether, polyoxypropylene glyceryl ether, polyoxyethylene lauryl ether, and trimethyl ether thereof.

The (poly)alkylene glycol compound is preferably a compound represented by Formula

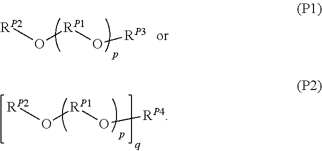

R^{P1} in the formulae is an alkylene group (preferably having 1 to 12 carbon atoms, more preferably having 1 to 6 carbon atoms, and still more preferably having 1 to 3 carbon atoms), which may be a chain group or a cyclic group and may be linear or branched. R^{P2} and R^{P3} are a hydrogen atom or an alkyl group (preferably having 1 to 36 carbon atoms, more preferably having 2 to 24 carbon atoms, and still more preferably having 3 to 12 carbon atoms), which may be a chain group or a cyclic group and may be linear or branched. p is preferably an integer of 1 to 24 and more preferably an integer of 2 to 12.

R^{P4} is a q-valent linking group, and is preferably a linking group composed of an organic group and preferably a linking group composed of a hydrocarbon. Specific examples of the linking group composed of a hydrocarbon include a linking group of an alkane structure (preferably having 1 to 24 carbon atoms, more preferably having 2 to 12 carbon atoms, and still more preferably having 2 to 6 carbon atoms), a linking group of an alkene structure (preferably having 2 to 24 carbon atoms, more preferably having 2 to 12 carbon atoms, and still more preferably having 2 to 6 carbon atoms), and a linking group of an aryl structure (preferably having 6 to 22 carbon atoms, more preferably having 6 to 18 carbon atoms, and still more preferably having 6 to 10 carbon atoms).

q is preferably an integer of 2 to 8, more preferably an integer of 2 to 6, and still more preferably an integer of 2 to 4.

A weight-average molecular weight of the alcohol compound or the (poly)alkylene glycol compound used as the mold release agent is preferably 150 to 6,000, more preferably 200 to 3,000, still more preferably 250 to 2,000, and even more preferably 300 to 1,200.

In addition, examples of a commercially available product of the (poly)alkylene glycol compound which can be used in the present invention include OLFINE E1010 (manufactured by Nissin Chemical Co., Ltd.) and Brij35 (manufactured by Kishida Chemical Co., Ltd.).

<Solvent>

The composition for forming an imprint pattern according to the embodiment of the present invention preferably contains a solvent.

In a case of using a composition for forming an imprint pattern containing a solvent, for example, the solvent can be removed by drying to obtain a curable film. Here, in such a curable film after solvent removal, defects are likely to occur in the curable film, and it is considered that, according to the present invention, such defects can be effectively suppressed.

In the present invention, a content of the solvent in the composition for forming an imprint pattern is preferably 90.0% to 99.0% by mass, more preferably 92.0% to 99.0% by mass, and still more preferably 95.0% to 99.0% by mass with respect to the total mass of the composition for forming an imprint pattern.

Examples of the solvent contained in the composition for forming a pattern include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether or lactone is particularly preferable.

<Other Additives>

The composition for forming an imprint pattern according to the embodiment of the present invention may contain other additives, in addition to the polymerizable compound, polymerization initiator, mold release agent, and solvent described above. A surfactant, a sensitizer, an antioxidant, a polymerization inhibitor, and the like may be contained as the other additives.

Specific examples of the other additives contained in the composition for forming a pattern, which can be used in the present invention, include additives contained in compositions described in JP2013-036027A, JP2014-090133A, and JP2013-189537A, the contents of which are incorporated in the present specification. In addition, also regarding preparation of the composition for forming a pattern and a pattern producing method, reference can be made to the descriptions in the above-described publications, the contents of which are incorporated in the present specification.

<Physical Property Value and the Like>

A viscosity of a composition obtained by removing the solvent from the composition for forming an imprint pattern (that is, a composition prepared by mixing the components (solid content) other than the solvent in the composition for forming an imprint pattern) is preferably 20.0 mPa·s or lower, more preferably 15.0 mPa·s or lower, still more preferably 11.0 mPa·s or lower, and even more preferably 9.0 mPa·s or lower. The lower limit value of the above-described viscosity is not particularly limited, but can be, for example, 5.0 mPa·s or greater. The viscosity can be measured by a known method, and for example, is measured according to the following method.

The viscosity is measured using an E-type rotational viscometer RE85L manufactured by TOKI SANGYO CO., LTD. and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

A surface tension (γResist) of the composition obtained by removing the solvent from the composition for forming an imprint pattern is preferably 28.0 mN/m or greater and more preferably 30.0 mN/m or greater, and may be 32.0 mN/m or greater. By using the composition which has high surface tension, a capillary force is increased, and the composition can be filled into a mold pattern at high speed. The upper limit value of the surface tension is not particularly limited, but from the viewpoint of relation to the closely adhesive layer and of imparting ink jet suitability, is preferably 40.0 mN/m or lower and more preferably 38.0 mN/m or lower, and may be 36.0 mN/m or lower.

The surface tension of the composition obtained by removing the solvent from the composition for forming a pattern is measured at 23° C. using a surface tensiometer SURFACE TENS-IOMETER CBVP-A3 manufactured by Kyowa Interface Science Co., LTD. and a glass plate.

An Ohnishi parameter of the composition obtained by removing the solvent from the composition for forming an imprint pattern is preferably 5.0 or less, more preferably 4.0 or less, and still more preferably 3.7 or less. The lower limit value of the Ohnishi parameter of the composition for forming a pattern is not particularly specified, but may be, for example, 1.0 or more or further 2.0 or more.

For the solid content of the composition for forming an imprint pattern, the Ohnishi parameter can be determined by substituting the number of carbon atoms, the number of hydrogen atoms, and the number of oxygen atoms in all the constituent components into the following expression, respectively.

Ohnishi parameter=Sum of number of carbon atoms, number of hydrogen atoms, and number of oxygen atoms/(Number of carbon atoms−Number of oxygen atoms)

<Preservation Container>

As a storage container of the composition for forming an imprint pattern according to the embodiment of the present invention, a storage container well known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

(Cured Substance and Imprint Pattern Producing Method)

The cured substance according to the embodiment of the present invention is a cured substance obtained by curing the composition for forming an imprint pattern according to the embodiment of the present invention.

The cured substance according to the embodiment of the present invention is preferably a patterned cured substance (imprint pattern).

Hereinafter, an imprint pattern producing method will be described.

<Imprint Pattern Producing Method>

The imprint pattern producing method according to the embodiment of the present invention includes an applying step of applying the composition for forming an imprint pattern according to the embodiment of the present invention onto a member to be applied, which is selected from the group consisting of a support and a mold;
a contact step of contacting a member which is not selected as the member to be applied from the group consisting of the support and the mold with the composition for forming an imprint pattern as a contact member;
a curing step of forming the composition for forming an imprint pattern into a cured substance; and
a peeling step of peeling off the mold from the cured substance.

[Applying Step]

The imprint pattern producing method according to the embodiment of the present invention includes an applying step of applying the composition for forming an imprint pattern according to the embodiment of the present invention to a member to be applied, which is selected from the group consisting of a support and a mold.

In the applying step, one member selected from the group consisting of the support and the mold is selected as the member to be applied, and the composition for forming an imprint pattern according to the embodiment of the present invention is applied to the selected member to be applied.

Among the support and the mold, one is selected as the member to be applied and the other is a contact member.

That is, in the applying step, the composition for forming an imprint pattern according to the embodiment of the present invention may be applied to the support and then brought into contact with the mold, or may be applied to the mold and then brought into contact with the support (may have a closely adhesive layer or the like described later).

—Support—

As the support, reference can be made to the description in paragraph 0103 of JP2010-109092A (the corresponding US application is the specification of US2011/0199592A), the contents of which are incorporated in the present specification. Specific examples thereof include a silicon substrate, a glass substrate, a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Furthermore, specific examples of a material for the glass substrate include aluminosilicate glass, aluminoborosilicate glass, and barium borosilicate glass. In the present invention, as the substrate, a silicon substrate is preferable.

It is preferable that the above-described support is a member including a closely adhesive layer on a surface on a side to which the composition for forming an imprint pattern is applied.

The closely adhesive layer is preferably a closely adhesive layer formed by applying a composition for forming a closely adhesive layer, which will be described later, to the support.

Moreover, the above-described support may further include a liquid film described later on a surface of the closely adhesive layer opposite to the side in contact with the support.

The liquid film is preferably a liquid film formed by applying a composition for forming a liquid film, which will be described later, to the closely adhesive layer.

As the above-described closely adhesive layer, the closely adhesive layers described in paragraphs 0017 to 0068 of JP2014-024322A, paragraphs 0016 to 0044 of JP2013-093552A, JP2014-093385A, JP2013-202982A, and the like can be used, the contents of which are incorporated in the present specification.

—Mold—

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. As the mold used in the present invention, a quartz mold is preferable. A pattern (line width) of the mold used in the present invention preferably has a size of 50 nm or less. The pattern of the mold can be formed according to a desired processing accuracy, for example, by photolithography, an electron beam drawing method, or the like, but in the present invention, a mold pattern producing method is not particularly limited.

Moreover, as the imprint pattern, a mold in which an imprint pattern including any shape of a line, a hole, or a pillar is formed is preferable.

Among them, a mold in which an imprint pattern including any shape of a line, a hole, or a pillar with a size of 100 nm or lower is formed is preferable.

—Application Method—

A method of applying the composition for forming an imprint pattern according to the embodiment of the present invention to the member to be applied is not particularly specified, and generally well-known application methods can be adopted. Examples thereof include a dip coating method, an air knife coating method, a curtain coating method, a wire bar coating method, a gravure coating method, an extrusion coating method, a spin coating method, a slit scanning method, and an ink jet method.

Among them, preferred examples thereof include an ink jet method and a spin coating method.

Moreover, the composition for forming an imprint pattern may be applied through multiple applying.

In a method of arranging liquid droplets by the ink jet method, a volume of the liquid droplets is preferably approximately 1 to 20 pL, and the liquid droplets are preferably arranged on the surface of the support at an interval between the liquid droplets. The interval between the liquid droplets may be appropriately set according to the volume of the liquid droplets, and is preferably an interval of 10 to 1,000 m. In a case of the ink jet method, the interval between liquid droplets is an arrangement interval between ink jet nozzles.

The ink jet method has an advantage that a loss of the composition for forming an imprint pattern is small.

Specific examples of the method of applying the composition for forming an imprint pattern by the ink jet method include the methods described in JP2015-179807A, WO2016/152597A, and the like, and the methods described in these documents can also be suitably used in the present invention.

On the other hand, the spin coating method has an advantage that the coating process is highly stable and the choice of materials which can be used is expanded.

Specific examples of the method of applying the composition for forming an imprint pattern by the spin coating method include the methods described in JP2013-095833A, JP2015-071741A, and the like, and the methods described in these documents can also be suitably used in the present invention.

—Drying Step—

Moreover, the imprint pattern producing method according to the embodiment of the present invention may further include a drying step of drying the composition for forming an imprint pattern according to the embodiment of the present invention applied in the applying step.

In particular, in a case where a composition including a solvent is used as the composition for forming an imprint pattern according to the embodiment of the present invention, it is preferable that the imprint pattern producing method according to the embodiment of the present invention includes the drying step.

In the drying step, at least a part of the solvent included in the composition for forming an imprint pattern according to the embodiment of the present invention applied is removed.

A drying method is not particularly limited, and drying by heating, drying by blowing air, or the like can be used without particular limitation, but drying by heating is preferable.

A heating unit is not particularly limited, and a well-known hot plate, oven, infrared heater, or the like can be used.

In the present invention, a layer formed from the composition for forming an imprint pattern after the applying step and the drying step performed as necessary and before the contact step is also referred to as a “curable film”.

By using the composition for forming an imprint pattern according to the embodiment of the present invention, the defects in the curable film over time are suppressed.

[Contact Step]

The imprint pattern producing method according to the embodiment of the present invention includes a contact step of contacting a member which is not selected as the member to be applied from the group consisting of the support and the mold with the above-described composition for forming an imprint pattern (curable film) as a contact member.

In a case where the support is selected as the member to be applied in the above-described applying step, in the contact step, the mold, which is the contact member, is brought into contact with the surface of the support to which the composition for forming an imprint pattern according to the embodiment of the present invention is applied (surface on which the curable film is formed).

In a case where the mold is selected as the member to be applied in the above-described applying step, in the contact step, the support, which is the contact member, is brought into contact with the surface of the mold to which the composition for forming an imprint pattern according to the embodiment of the present invention is applied (surface on which the curable film is formed).

That is, in the contact step, the composition for forming an imprint pattern according to the embodiment of the present invention is present between the member to be applied and the contact member.

Details of the support and the mold are as described above.

In a case where the composition for forming an imprint pattern according to the embodiment of the present invention (curable film) which is applied to the member to be applied is brought into contact with the contact member, a pressing pressure is preferably 1 MPa or lower. By setting the pressing pressure to 1 MPa or lower, the support or the mold is less likely to be deformed and thus the pattern accuracy tends to be improved. Moreover, also from the viewpoint that a device tends to be miniaturized due to low pressing force, the above-described range is preferable.

In addition, it is also preferable that the contact between the curable film and the contact member is performed under an atmosphere including a helium gas, a condensable gas, or both a helium gas and a condensable gas.

[Curing Step]

The imprint pattern producing method according to the embodiment of the present invention includes a curing step of forming a cured substance with the composition for forming an imprint pattern.

The curing step is performed after the above-described contact step and before the above-described peeling step.

The method for producing a cured substance according to the embodiment of the present invention includes a step of curing the composition for forming an imprint pattern, which is obtained by the method for producing a composition for forming an imprint pattern according to the embodiment of the present invention. The above-described curing step can be performed by the same method as the curing step in the imprint pattern producing method according to the embodiment of the present invention. Moreover, the above-described cured substance is preferably a cured substance in which the mold has been peeled off by the peeling step described later.

Examples of a curing method include curing by heating and curing by exposure, which may be determined according to the type of the polymerization initiator included in the composition for forming an imprint pattern, and curing by exposure is preferable.

For example, in a case where the above-described polymerization initiator is a photopolymerization initiator, the composition for forming an imprint pattern can be cured by performing exposure in the curing step.

An exposure wavelength is not particularly limited, and may be determined according to the polymerization initiator. For example, ultraviolet light or the like can be used.

An exposure light source may be determined according to the exposure wavelength, and examples thereof include g-rays (wavelength: 436 nm), h-rays (wavelength: 405 nm), i-rays (wavelength: 365 nm), broadband light (light including at least two wavelengths of light selected from the group consisting of three wavelengths of g-rays, h-rays, and i-rays, and light having a wavelength shorter than that of i-rays; examples thereof include a high-pressure mercury lamp in a case where an optical filter is not used), semiconductor laser (wavelength: 830 nm, 532 nm, 488 nm, 405 nm, and the like), metal halide lamp, excimer laser, KrF excimer laser (wavelength: 248 nm), ArF excimer laser (wavelength: 193 nm), F₂ excimer laser (wavelength: 157 nm), extreme ultraviolet rays (EUV; wavelength: 13.6 nm), and electron beam.

Among them, preferred examples thereof include exposure using i-rays or broadband light.

An irradiation amount (exposure amount) during the exposure may be sufficiently larger than the minimum irradiation amount required for curing the composition for forming an imprint pattern. The irradiation amount required for curing the composition for forming an imprint pattern can be appropriately determined by examining consumption or the like of an unsaturated bond of the composition for forming an imprint pattern.

The exposure amount is, for example, preferably in a range of 5 to 1,000 mJ/cm² and more preferably in a range of 10 to 500 mJ/cm².

An exposure illuminance is not particularly limited and may be selected depending on a relationship with the light source, but is preferably in a range of 1 to 500 mW/cm² and more preferably in a range of 10 to 400 mW/cm².

An exposure time is not particularly limited and may be determined in consideration of the exposure illuminance according to the exposure amount, but is preferably 0.01 to 10 seconds and more preferably 0.5 to 1 second.

A temperature of the support during the exposure is usually room temperature, but in order to increase reactivity, the exposure may be performed while heating. Since setting a vacuum state as a stage prior to the exposure is effective in preventing air bubbles from being mixed, suppressing a decrease in reactivity due to oxygen mixing, and improving adhesiveness between the mold and the composition for forming an imprint pattern, the light irradiation may be performed in a vacuum state. Moreover, a preferred degree of vacuum during the exposure is in a range of 101 Pa to normal pressure.

After the exposure, as necessary, the composition for forming an imprint pattern after the exposure may be heated. A heating temperature is preferably 150° C. to 280° C. and more preferably 200° C. to 250° C. Moreover, a heating time is preferably 5 to 60 minutes and more preferably 15 to 45 minutes.

In addition, in the curing step, only the heating step may be performed without exposure. For example, in a case where the above-described polymerization initiator is a thermal polymerization initiator, the composition for forming an imprint pattern can be cured by performing heating in the curing step. A preferred aspect of the heating temperature and heating time in this case is the same as in the heating temperature and heating time in the case of heating after the above-described exposure.

A heating unit is not particularly limited, and examples thereof include the same heating unit as in the heating of the above-described drying step.

[Peeling Step]

The imprint pattern producing method according to the embodiment of the present invention includes a peeling step of peeling off the cured substance from the mold.

By the peeling step, the cured substance obtained in the curing step is peeled off from the mold, and a cured substance in a patterned shape (also referred to as a “cured substance pattern”) to which the pattern of the mold is transferred can be obtained. The obtained cured substance pattern can be used for various uses as described later. In the present invention, the imprint pattern producing method is particularly advantageous in that a fine cured substance pattern of a nano order can be formed, and a cured substance pattern having a size of 50 nm or lower and particularly 30 nm or lower can also be formed. The lower limit value of the size of the above-described cured substance pattern is not particularly specified, but can be, for example, 1 nm or greater.

A peeling method is not particularly limited, and for example, the peeling can be performed by using a mechanical peeling device or the like known in the imprint pattern producing method.

(Device, Method for Manufacturing Device, and Application of Cured Substance Pattern)

The device according to the embodiment of the present invention includes the cured substance according to the embodiment of the present invention. In addition, the device according to the embodiment of the present invention can be obtained, for example, by the following method for manufacturing a device according to the embodiment of the present invention.

The method for manufacturing a device according to the embodiment of the present invention includes the imprint pattern producing method according to the embodiment of the present invention.

Specifically, a pattern (cured substance pattern) formed by the imprint pattern producing method according to the embodiment of the present invention can be used in a method for manufacturing a device such as a permanent film used in a liquid crystal display device (LCD) or the like, or an etching resist (mask for lithography) for manufacturing a semiconductor element.

In particular, the present invention describes a method for manufacturing a circuit board, which includes a step of obtaining a pattern (cured substance pattern) by the imprint pattern producing method according to the embodiment of the present invention, and a method for manufacturing a device including the circuit board. The method for manufacturing a circuit board according to the preferred embodiment of the present invention may further include a step of performing etching or ion implantation on the substrate using the pattern (cured substance pattern) obtained by the above-described pattern forming method as a mask and a step of forming an electronic member. The above-described circuit board is preferably a semiconductor element. That is, the present invention describes a method for manufacturing a semiconductor device, including the imprint pattern producing method according to the embodiment of the present invention. Further, the present invention describes a method for manufacturing a device, which includes a step of obtaining a circuit board by the above-described method for manufacturing a circuit board and a step of connecting the circuit board and a control mechanism which controls the circuit board.

Moreover, by forming a grid pattern on a glass substrate of a liquid crystal display device using the imprint pattern producing method according to the embodiment of the present invention, a polarizing plate having low reflection or absorption and a large screen size (for example, 55 inches, or greater than 60 inches) can be manufactured at a low cost. That is, the present invention describes a method for manufacturing a polarizing plate and a method for manufacturing a device including the polarizing plate, which include the imprint pattern producing method according to the embodiment of the present invention. For example, the polarizing plate described in JP2015-132825A or WO2011/132649A can be manufactured. Furthermore, 1 inch is 25.4 mm.

The pattern (cured substance pattern) manufactured by the imprint pattern producing method according to the embodiment of the present invention is also useful as an etching resist (mask for lithography). That is, the present invention describes a method for manufacturing a device in which the obtained cured substance pattern is used as an etching resist, including the imprint pattern producing method according to the embodiment of the present invention.

In a case where the cured substance pattern is used as an etching resist, examples thereof include an aspect in which, first, a pattern (cured substance pattern) is formed by applying the imprint pattern producing method according to the embodiment of the present invention on the support, and the obtained cured substance pattern is used as an etching mask to etch the support. By performing etching with an etching gas such as hydrogen fluoride or the like in a case of wet etching and CF₄ or the like in a case of dry etching, a pattern can be formed on the support along the shape of the desired cured substance pattern.

Moreover, the pattern (cured substance pattern) produced by the imprint pattern producing method according to the embodiment of the present invention can be also preferably used for producing a recording medium such as a magnetic disc, a light-receiving element such as a solid-state imaging element, a light emitting element such as a light emitting diode (LED) and organic electroluminescence (organic EL), an optical device such as a liquid crystal display device (LCD), an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

That is, the present invention describes a method for manufacturing these devices, including the imprint pattern producing method according to the embodiment of the present invention.

<Composition for Forming Closely Adhesive Layer>

As described above, by providing the closely adhesive layer between the support and the composition for forming an imprint pattern, effects such as improvement in adhesiveness between the support and a composition layer for forming an imprint pattern can be achieved. In the present invention, the closely adhesive layer can be obtained by applying the composition for forming a closely adhesive layer to the support and then curing the composition, in the same manner as the composition for forming an imprint pattern. Hereinafter, each component of the composition for forming a closely adhesive layer will be described.

The composition for forming a closely adhesive layer includes a curable component. The curable component is a component constituting the closely adhesive layer, and may be any one of a high-molecular-weight component (for example, a molecular weight is more than 1,000) or a low-molecular-weight component (for example, a molecular weight is less than 1,000). Specific examples thereof include a resin and a crosslinking agent. Each of these components may be used alone or in combination of two or more kinds thereof.

A total content of the curable components in the composition for forming a closely adhesive layer is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or lower.

A concentration of the curable component in the composition for forming a closely adhesive layer (including a solvent) is not particularly limited, but is preferably 0.01% by mass or greater, more preferably 0.05% by mass or greater, and still more preferably 0.1% by mass or greater. The upper limit thereof is preferably 10% by mass or lower, more preferably 5% by mass or lower, still more preferably 1% by mass or lower, and even more preferably lower than 1% by mass.

[Resin]

As the resin in the composition for forming a closely adhesive layer, a well-known resin can be widely used. The resin used in the present invention preferably has at least one of a radically polymerizable group or a polar group, and more preferably has both a radically polymerizable group and a polar group.

By having the radically polymerizable group, a closely adhesive layer having excellent hardness can be obtained. Moreover, by having the polar group, adhesiveness to the support is improved. Furthermore, in a case where a crosslinking agent is formulated, a crosslinking structure formed after curing is further firmed, and thus hardness of the obtained closely adhesive layer can be improved.

The radically polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, and a (meth)acryloyl group or a vinyl group is preferable, a (meth)acryloyl group is more preferable, and a (meth)acryloyloxy group is still more preferable. The ethylenically unsaturated bond-containing group defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxy group, or a hydroxy group, more preferably at least one kind of an alcoholic hydroxy group, a phenolic hydroxy group, or a carboxy group, and still more preferably an alcoholic hydroxy group or a carboxy group. The polar group defined here is referred to as a polar group Po. The polar group is preferably a nonionic group.

The resin in the composition for forming a closely adhesive layer may further include a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at least one kind of a (meth)acrylic resin, a vinyl resin, or a novolac resin is preferable.

A weight-average molecular weight of the resin is preferably 4,000 or more, more preferably 6,000 or more, and still more preferably 8,000 or more. The upper limit thereof is preferably 1,000,000 or less and may be 500,000 or less.

The resin preferably has at least one of constitutional units represented by Formulae (1) to (3).

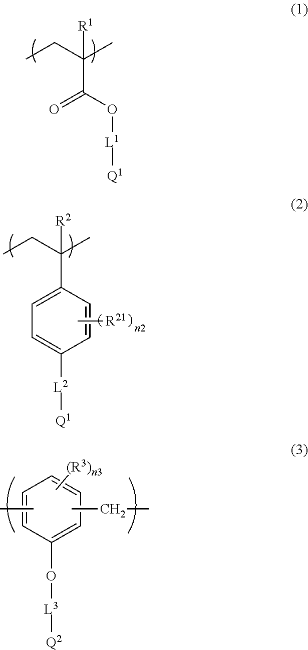

In the formulae, R¹ and R² are each independently a hydrogen atom or a methyl group. R²¹ and R³ are each independently a substituent. L¹, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are each preferably a methyl group.

R²¹ and R³ are each independently preferably the substituent T.

In a case where there is a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring Cf) (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocycle (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocycle (rings exemplified below are referred to as a ring Co) (a furan ring, a pyran ring, an oxirane ring, an oxetane ring, a tetrahydrofuran ring, a tetrahydropyran ring, a dioxane ring, and the like), and a sulfur-containing heterocycle (rings exemplified below are referred to as a ring Cs) (a thiophene ring, a thiirane ring, a thietane ring, a tetrahydrothiophene ring, a tetrahydrothiopyran ring, and the like).

In a case where there is a plurality of R³'s, R³'s may be linked to each other to form a cyclic structure. Examples of the formed cyclic structure include ring Cf, the ring Cr, the ring Cn, the ring Co, and the ring Cs.

It is preferable that L¹, L², and L³ are each independently a single bond or a linking group L which will be described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxy group as a substituent is also preferable. In the present specification, the “(oligo)alkyleneoxy group” means a divalent linking group having one or more “alkyleneoxy” constitutional units. The number of carbon atoms in an alkylene chain in the constitutional unit may be the same or different for every constitutional unit.

n2 is preferably 0 or 1 and more preferably 0. n3 is preferably 0 or 1 and more preferably 0.

Q¹ is preferably the ethylenically unsaturated bond-containing group Et.

Q² is preferably a polar group, and preferably an alkyl group having an alcoholic hydroxy group.

The above-described resin may further include at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

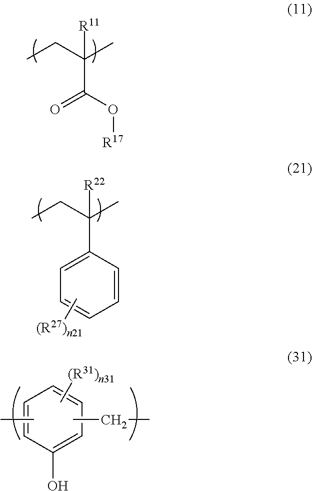

In the formulae, R¹¹ and R²² are each independently a hydrogen atom or a methyl group. R⁷ is a substituent. R²⁷ is a substituent. n21 is an integer of 0 to 5. R³¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po, and more preferably the polar group Po or the substituent T substituted with the polar group Po. In a case where R¹⁷ is a group containing a cyclic ether group, R¹⁷ is preferably a group containing the cyclic ether group Cyt, and more preferably the substituent T substituted with the cyclic ether group Cyt.

R²⁷ is a substituent, and at least one of R²⁷'s is preferably a polar group. The substituent is preferably the substituent T. n21 is preferably 0 or 1 and more preferably 0.

In a case where there is a plurality of R²⁷'s, R²⁷'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there is a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of carbon atoms is preferably 1 to 24, more preferably 1 to 12, and still more preferably 1 to 6), an alkenylene group (the number of carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the repetition number is preferably 1 to 50, more preferably 1 to 40, and still more preferably 1 to 30), an arylene group (the number of carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxy group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂—(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and as necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

The resin may be used alone or in combination of a plurality thereof.

As the resin as the curable component, in addition to the above-described resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

[Crosslinking Agent]

The crosslinking agent in the composition for forming a closely adhesive layer is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and thus a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

[Other Components]

The composition for forming a closely adhesive layer may include other components in addition to the above-described components.

Specifically, one kind or two or more kinds of a solvent, a thermal acid generator, an alkylene glycol compound, a polymerization initiator, a polymerization inhibitor, an antioxidant, a leveling agent, a thickener, a surfactant, or the like may be included. Regarding the above-described components, the respective components described in JP2013-036027A, JP2014-090133A, and JP2013-189537A can be used. Also regarding the content or the like, reference can be made to the description in the above-described publications.

—Solvent—

In the present invention, the composition for forming a closely adhesive layer particularly preferably contains a solvent (hereinafter, also referred to as a “solvent for a closely adhesive layer”). The solvent is, for example, preferably a compound which is liquid at 23° C. and has a boiling point of 250° C. or lower. A content of the solvent for a closely adhesive layer in the composition for forming a closely adhesive layer is preferably 99.0% by mass or greater and more preferably 99.2% by mass or greater, and may be 99.4% by mass or greater. That is, the concentration of the total solid content in the composition for forming a closely adhesive layer is preferably 1% by mass or lower, more preferably 0.8% by mass or lower, and still more preferably 0.6% by mass or lower. Moreover, the lower limit value thereof is preferably greater than 0% by mass, more preferably 0.001% by mass or greater, still more preferably 0.01% by mass or greater, and even more preferably 0.1% by mass or greater. By setting the proportion of the solvent within the above-described range, a film thickness during film formation is kept thin, and thus pattern formability during etching processing tends to be improved.

Only one kind or two or more kinds of the solvents may be contained in the composition for forming a closely adhesive layer. In a case where two or more kinds thereof are contained, the total amount thereof is preferably within the above-described range.

A boiling point of the solvent for a closely adhesive layer is preferably 230° C. or lower, more preferably 200° C. or lower, still more preferably 180° C. or lower, even more preferably 160° C. or lower, and even still more preferably 130° C. or lower. The lower limit value thereof is preferably 23° C. or higher and more preferably 60° C. or higher. By setting the boiling point within the above-described range, the solvent can be easily removed from the closely adhesive layer, which is preferable.

The solvent for a closely adhesive layer is preferably an organic solvent. The solvent is preferably a solvent having any one or more of an ester group, a carbonyl group, a hydroxy group, or an ether group. Among them, it is preferable to use an aprotic polar solvent.

Examples of a preferred solvent among the solvents for a closely adhesive layer include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether and lactone are particularly preferable.

<Composition for Forming Liquid Film>

In addition, in the present invention, it is also preferable that a liquid film is formed on the closely adhesive layer by using a composition for forming a liquid film containing a radically polymerizable compound which is a liquid at 23° C. and 1 atm. In the present invention, the liquid film can be obtained by applying the composition for forming a liquid film onto the support and then drying the composition, in the same manner as the composition for forming an imprint pattern. By forming such a liquid film, there are effects that the adhesiveness between the support and the composition for forming an imprint pattern is further improved, and that the wettability of the composition for forming an imprint pattern on the support is also improved. Hereinafter, the composition for forming a liquid film will be described.

The viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or greater. The viscosity is measured according to the following method.

The viscosity is measured using an E-type rotational viscometer RE85L manufactured by TOKI SANGYO CO., LTD. and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

[Radically Polymerizable Compound A]

The composition for forming a liquid film contains a radically polymerizable compound (radically polymerizable compound A) which is a liquid at 23° C. and 1 atm.

A viscosity of the radically polymerizable compound A at 23° C. is preferably 1 to 100,000 mPa·s. The lower limit thereof is preferably 5 mPa·s or greater and more preferably 11 mPa·s or greater. The upper limit thereof is preferably 1,000 mPa·s or lower and more preferably 600 mPa·s or lower.

The radically polymerizable compound A may be a monofunctional radically polymerizable compound having only one radically polymerizable group in one molecule, or a polyfunctional radically polymerizable compound having two or more radically polymerizable groups in one molecule. The monofunctional radically polymerizable compound and the polyfunctional radically polymerizable compound may be used in combination. Among them, for a reason of suppressing pattern collapse, the radically polymerizable compound A contained in the composition for forming a liquid film preferably includes a polyfunctional radically polymerizable compound, more preferably includes a radically polymerizable compound having two to five radically polymerizable groups in one molecule, still more preferably includes a radically polymerizable compound having two to four radically polymerizable groups in one molecule, and particularly preferably includes a radically polymerizable compound having two radically polymerizable groups in one molecule.

Furthermore, the radically polymerizable compound A preferably contains at least one of an aromatic ring (the number of carbon atoms is preferably 6 to 22, more preferably 6 to 18, and still more preferably 6 to 10) or an alicyclic ring (the number of carbon atoms is preferably 3 to 24, more preferably 3 to 18, and still more preferably 3 to 6), and more preferably contains an aromatic ring. The aromatic ring is preferably a benzene ring. Moreover, a molecular weight of the radically polymerizable compound A is preferably 100 to 900.

Examples of the radically polymerizable group of the radically polymerizable compound A include ethylenically unsaturated bond-containing groups, such as a vinyl group, an allyl group, and a (meth)acryloyl group, and a (meth)acryloyl group is preferable.

It is also preferable that the radically polymerizable compound A is a compound represented by Formula (I-1).

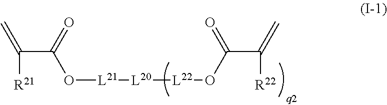

L²⁰ is a (1+q2)-valent linking group, and examples thereof include (1+q2)-valent linking groups which contain a group (the number of carbon atoms is preferably 1 to 12, more preferably 1 to 6, and still more preferably 1 to 3) having an alkane structure, a group (the number of carbon atoms is preferably 2 to 12, more preferably 2 to 6, and still more preferably 2 or 3) having an alkene structure, a group (the number of carbon atoms is preferably 6 to 22, more preferably 6 to 18, and still more preferably 6 to 10) having an aryl structure, a group (the number of carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, or a 7-membered ring are preferable) having a heteroaryl structure, or a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group including at least one kind selected from a group having an aryl structure or a group having a heteroaryl structure, and more preferably a linking group including a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other through or without the linking group L to form a ring. L²⁰, L²¹, and L²² may have the above-described substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the radically polymerizable compound A, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the radically polymerizable compound A in the composition for forming a liquid film is preferably 0.01% by mass or greater, more preferably 0.05% by mass or greater, and still more preferably 0.1% by mass or greater. The upper limit thereof is preferably 10% by mass or lower, more preferably 5% by mass or lower, and still more preferably 1% by mass or lower.

The content of the radically polymerizable compound A in the solid content of the composition for forming a liquid film is preferably 50% by mass or greater, more preferably 75% by mass or greater, and still more preferably 90% by mass or greater. The upper limit thereof may be 100% by mass. The radically polymerizable compound A may be used alone or in combination of two or more kinds thereof. In a case where two or more kinds thereof are used, the total amount thereof is preferably within the above-described range.

Furthermore, it is also preferable that the solid content of the composition for forming a liquid film substantially consists of the radically polymerizable compound A. The case where the solid content of the composition for forming a liquid film substantially consists of the radically polymerizable compound A means that the content of the radically polymerizable compound A in the solid content of the composition for forming a liquid film is 99.9% by mass or greater, the content is more preferably 99.99% by mass or greater, and it is still more preferable that the solid content consists of the radically polymerizable compound A.

[Solvent]

The composition for forming a liquid film preferably contains a solvent (hereinafter, referred to as a “solvent for a liquid film” in some cases). Examples of the solvent for a liquid film include the solvents described in the above-described section of the solvent for a closely adhesive layer, and these solvents can be used. A content of the solvent for a liquid film in the composition for forming a liquid film is preferably 90% by mass or greater and more preferably 99% by mass or greater, and may be 99.99% by mass or greater.

A boiling point of the solvent for a liquid film is preferably 230° C. or lower, more preferably 200° C. or lower, still more preferably 180° C. or lower, even more preferably 160° C. or lower, and even still more preferably 130° C. or lower. The lower limit value thereof is preferably 23° C. and more preferably 60° C. or higher. By setting the boiling point within the above-described range, the solvent can be easily removed from the liquid film, which is preferable.

[Radical Polymerization Initiator]

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, or an oxime compound is preferable. Examples of a commercially available product thereof include IRGACURE-OXE01, IRGACURE-OXE02, IRGACURE-127, IRGACURE-819, IRGACURE-379, IRGACURE-369, IRGACURE-754, IRGACURE-1800, IRGACURE-651, IRGACURE-907, IRGACURE-TPO, and IRGACURE-1173 (all manufactured by BASF SE), and Omnirad 184, Omnirad TPO H, Omnirad 819, and Omnirad 1173 (all manufactured by IGM Resins B.V.).

In a case where the radical polymerization initiator is contained, the content thereof with respect to the solid content of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above-described range.

[Other Components]

The composition for forming a liquid film may include one kind or two or more kinds of a polymerization inhibitor, an antioxidant, a leveling agent, a thickener, a surfactant, or the like, in addition to the above-described components.

### EXAMPLES

Hereinafter, the present invention will be described in more detail with reference to Examples. The materials, the used amounts, the proportions, the treatment details, the treatment procedures, and the like shown in the following Examples can be appropriately modified without departing from the spirit of the present invention. Therefore, the scope of the present invention is not limited to the specific examples described below. In Examples, unless otherwise specified, “parts” and “%” are based on mass, and an environmental temperature (room temperature) in each step is 23° C.

<Preparation of Composition for Forming Imprint Pattern>

For each Example and each Comparative Example, various compounds described in the tables below were mixed, and 4-hydroxy-2,2,6,6-tetramethylpiperidine-1-oxyl free radical (manufactured by Tokyo Chemical Industry Co., Ltd.) as a polymerization inhibitor was added thereto so that an amount thereof was 200 ppm by mass (0.02% by mass) with respect to the total amount of a polymerizable compound, thereby preparing a composition. The content of each component other than a solvent is a content (part by mass) shown in the tables, and as for the content of the solvent, the concentration of solid contents of each composition is set to the value described in the column of “Concentration of solid contents (% by mass)” in the tables. The description of “100” in the column of “Solvent” means that the solvent was used alone. Moreover, in each composition, a component described as “-” was not added. The composition was filtered through a 0.02 m Nylon filter and a 0.001 μm UPE filter to prepare a composition for forming an imprint pattern and a comparative composition.

TABLE 1

| | | Example | | | | | | | | | |
|---|---|---|---|---|---|---|---|---|---|---|---|
| | | 1 | 2 | 3 | 4 | 5 | 6 | 7 | 8 | 9 | 10 |
| Polymerizable | A-1 | 96 | 96 | 96 | 96 | 96 | 96 | 96 | 96 | 96 | 96 |
| compound | A-2 | — | — | — | — | — | — | — | — | — | — |
| | A-3 | — | — | — | — | — | — | — | — | — | — |
| | A-4 | — | — | — | — | — | — | — | — | — | — |
| | A-5 | — | — | — | — | — | — | — | — | — | — |
| | A-6 | — | — | — | — | — | — | — | — | — | — |
| | A-7 | — | — | — | — | — | — | — | — | — | — |
| | A-8 | — | — | — | — | — | — | — | — | — | — |
| | A-9 | — | — | — | — | — | — | — | — | — | — |
| | A-10 | — | — | — | — | — | — | — | — | — | — |
| | A-11 | — | — | — | — | — | — | — | — | — | — |
| Photopolymerization | B-1 | 2.7 | 0.3 | 1.5 | 2.37 | 2.55 | 2.85 | 10.8 | 4.5 | — | — |
| initiator | B-2 | 0.3 | 2.7 | 1.5 | 0.63 | 0.45 | 0.15 | 1.2 | 0.5 | — | — |
| | B-3 | — | — | — | — | — | — | — | — | 2.7 | — |
| | B-4 | — | — | — | — | — | — | — | — | 0.3 | — |
| | B-5 | — | — | — | — | — | — | — | — | — | 2.7 |
| | B-6 | — | — | — | — | — | — | — | — | — | 0.3 |
| | B-7 | — | — | — | — | — | — | — | — | — | — |
| | B-8 | — | — | — | — | — | — | — | — | — | — |
| Mold release | C-1 | 1 | 1 | 1 | 1 | 1 | 1 | 1 | 1 | 1 | 1 |
| agent | C-2 | — | — | — | — | — | — | — | — | — | — |
| | C-3 | — | — | — | — | — | — | — | — | — | — |
| Others | Z-1 | — | — | — | — | — | — | — | — | — | — |
| | Z-2 | — | — | — | — | — | — | — | — | — | — |
| Solvent | D-1 | 100 | 100 | 100 | 100 | 100 | 100 | 100 | 100 | 100 | 100 |
| Concentration of solid contents | | 4 | 4 | 4 | 4 | 4 | 4 | 4 | 4 | 4 | 4 |
| Evaluation | Film | B | A | A | A | A | A | C | B | A | A |
| | stability | | | | | | | | | | |

| | | | | | | | | | | |
|---|---|---|---|---|---|---|---|---|---|---|
| Film thickness | 100 | 100 | 100 | 100 | 100 | 100 | 100 | 100 | 100 | 100 |

| | | Example | | | | | | | | | |
|---|---|---|---|---|---|---|---|---|---|---|---|
| | | 11 | 12 | 13 | 14 | 15 | 16 | 17 | 18 | 19 | 20 |
| Polymerizable | A-1 | — | — | — | — | — | — | — | — | — | — |
| compound | A-2 | 96 | — | — | — | — | — | — | — | — | — |
| | A-3 | — | 96 | — | — | — | — | — | — | — | — |
| | A-4 | — | — | 96 | — | — | — | — | — | — | — |
| | A-5 | — | — | — | 96 | — | — | — | — | — | — |
| | A-6 | — | — | — | — | 96 | — | — | — | — | — |
| | A-7 | — | — | — | — | — | 96 | — | — | — | — |
| | A-8 | — | — | — | — | — | — | 96 | — | — | — |
| | A-9 | — | — | — | — | — | — | — | 96 | — | — |
| | A-10 | — | — | — | — | — | — | — | — | 96 | — |
| | A-11 | — | — | — | — | — | — | — | — | — | 96 |
| Photopolymerization | B-1 | 2.7 | 2.7 | 2.7 | 2.7 | 2.7 | 2.7 | 2.7 | 2.7 | 2.7 | 2.7 |
| initiator | B-2 | 0.3 | 0.3 | 0.3 | 0.3 | 0.3 | 0.3 | 0.3 | 0.3 | 0.3 | 0.3 |
| | B-3 | — | — | — | — | — | — | — | — | — | — |
| | B-4 | — | — | — | — | — | — | — | — | — | — |
| | B-5 | — | — | — | — | — | — | — | — | — | — |
| | B-6 | — | — | — | — | — | — | — | — | — | — |
| | B-7 | — | — | — | — | — | — | — | — | — | — |
| | B-8 | — | — | — | — | — | — | — | — | — | — |
| Mold release | C-1 | 1 | 1 | 1 | 1 | 1 | 1 | 1 | 1 | 1 | 1 |
| agent | C-2 | — | — | — | — | — | — | — | — | — | — |
| | C-3 | — | — | — | — | — | — | — | — | — | — |
| Others | Z-1 | — | — | — | — | — | — | — | — | — | — |
| | Z-2 | — | — | — | — | — | — | — | — | — | — |
| Solvent | D-1 | 100 | 100 | 100 | 100 | 100 | 100 | 100 | 100 | 100 | 100 |
| Concentration of solid contents | | 4 | 4 | 4 | 4 | 4 | 4 | 4 | 4 | 4 | 4 |
| Evaluation | Film | A | A | A | A | A | A | A | A | A | A |
| | stability | | | | | | | | | | |

| | | | | | | | | | | |
|---|---|---|---|---|---|---|---|---|---|---|
| Film thickness | 100 | 100 | 100 | 100 | 100 | 100 | 100 | 100 | 100 | 100 |

TABLE 2

| | | | | | | | | | | | | Comparative | |
|---|---|---|---|---|---|---|---|---|---|---|---|---|---|
| | | Example | | | | | | | | | | Example | |
| | | 21 | 22 | 23 | 24 | 25 | 26 | 27 | 28 | 29 | 30 | 1 | 2 |
| Polymerizable | A-1 | 96 | 96 | 96 | 96 | 96 | 96 | 96 | 96 | 96 | 96 | 96 | 96 |
| compound | A-2 | — | — | — | — | — | — | — | — | — | — | — | — |
| | A-3 | — | — | — | — | — | — | — | — | — | — | — | — |
| | A-4 | — | — | — | — | — | — | — | — | — | — | — | — |
| | A-5 | — | — | — | — | — | — | — | — | — | — | — | — |
| | A-6 | — | — | — | — | — | — | — | — | — | — | — | — |
| | A-7 | — | — | — | — | — | — | — | — | — | — | — | — |
| | A-8 | — | — | — | — | — | — | — | — | — | — | — | — |
| | A-9 | — | — | — | — | — | — | — | — | — | — | — | — |
| | A-10 | — | — | — | — | — | — | — | — | — | — | — | — |
| | A-11 | — | — | — | — | — | — | — | — | — | — | — | — |
| Photopolymerization | B-1 | 2.7 | 2.7 | 2.7 | — | — | 2.7 | 1 | 2.7 | 2.7 | 2.7 | 3 | 2.7 |
| initiator | B-2 | 0.3 | 0.3 | — | — | — | 0.2 | 1 | 0.3 | 0.3 | 0.3 | — | — |
| | B-3 | — | — | — | — | — | — | — | — | — | — | — | — |
| | B-4 | — | — | — | — | — | — | — | — | — | — | — | — |
| | B-5 | — | — | — | 2.7 | — | — | — | — | — | — | — | — |
| | B-6 | — | — | — | — | — | — | — | — | — | — | — | — |
| | B-7 | — | — | — | — | 2.7 | — | 1 | — | — | — | — | 0.3 |
| | B-8 | — | — | — | — | 0.3 | — | — | — | — | — | — | — |
| Mold release | C-1 | 1 | 1 | 1 | 1 | 1 | 1 | 1 | 2 | — | — | 1 | 1 |
| agent | C-2 | — | — | — | — | — | — | — | — | 1 | — | — | 1 |
| | C-3 | — | — | — | — | — | — | — | — | — | 1 | — | — |
| Others | Z-1 | — | — | 0.3 | — | — | 0.1 | — | — | — | — | — | — |
| | Z-2 | — | — | — | 0.3 | — | — | — | — | — | — | — | — |
| Solvent | D-1 | 100 | 100 | — | — | — | — | — | 100 | 100 | 100 | 100 | 100 |
| Concentration of solid contents | | 2.5 | 1.5 | 4 | 4 | 4 | 4 | 4 | 4 | 4 | 4 | 4 | 4 |
| Evaluation | Film | B | C | A | A | B | B | C | B | B | B | D | D |
| | stability | | | | | | | | | | | | |

| | | | | | | | | | | | | |
|---|---|---|---|---|---|---|---|---|---|---|---|---|
| Film thickness | 60 | 30 | 100 | 100 | 100 | 100 | 100 | 100 | 100 | 100 | 100 | 100 |

Details of each of the components listed in the tables are as follows.

[Polymerizable Compound]
A-1 to A-11: compounds shown in Table 3 below

[Polymerization Initiator (Photopolymerization Initiator)]
B-1: Omnirad TPO H (manufactured by IGM Resins B.V)
B-2: Omnirad TPO L (manufactured by IGM Resins B.V)
B-3: Omnirad 369E (manufactured by IGM Resins B.V)
B-4: Omnirad 379EG (manufactured by IGM Resins B.V)
B-5: Omnirad 1173 (manufactured by IGM Resins B.V)
B-6: Omnirad 184 (manufactured by IGM Resins B.V)
B-7: Irgacure ONE 02 (manufactured by BASF SE)
B-8: Irgacure OXE 01 (manufactured by BASF SE)

In addition, a structure of each photopolymerization initiator is as shown in Table 4 below.

Here, B-1, B-2, and Z-1, B-3 and B-4, B-5, B-6, and Z-2, and B-7 and B-8 are related to each other as derivatives.

[Mold Release Agent]
C-1: compound having the following structure
C-2: OLFINE E 1010 (manufactured by Nissin Chemical Co., Ltd.)
C-3: Brij35 (manufactured by Kishida Chemical Co., Ltd.)

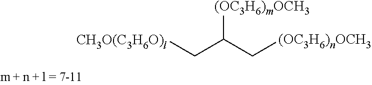

[Solvent]
D-1: propylene glycol monomethyl ether acetate (PGMEA)

[Others (Other Additives)]
Z-1 and Z-2: compounds shown in Table 5 below

TABLE 3

| Classi- | | | |
|---|---|---|---|
| fication | Name | Mw | Structural formula |
| A-1 | Silicone-containing | 2500 | Silicone-containing acrylate resin synthesized from silicone |
| | acrylate resin 1 | | resin X-40-9225 (manufactured by Shin-Etsu Chemical Co., |
| | | | Ltd.) and 2-hydroxyethyl acrylate |
| A-2 | Silicone-containing | 2050 | Silicone-containing acrylate resin synthesized from silicone |
| | acrylate resin 2 | | resin KR-510 (manufactured by Shin-Etsu Chemical Co., Ltd.) |
| | | | and 2-hydroxyethyl acrylate |
| A-3 | Silicone-containing | 2050 | Silicone-containing acrylate resin synthesized from silicone |
| | acrylate resin 3 | | resin X-40-9225 (manufactured by Shin-Etsu Chemical Co., |
| | | | Ltd.) and 2-hydroxyethyl acrylate |
| A-4 | Silicone-containing | 2500 | Silicone-containing acrylate resin synthesized from silicone |
| | acrylate resin 4 | | resin X-40-9225 (manufactured by Shin-Etsu Chemical Co., |
| | | | Ltd.) and 2-hydroxyethyl acrylate |
| A-5 | Silicone-containing | 1650 | Silicone-containing acrylate resin synthesized from silicone |
| | acrylate resin 5 | | resin KR-500 (manufactured by Shin-Etsu Chemical Co., Ltd.) |
| | | | and 2-hydroxyethyl acrylate |
| A-6 | Silicone-containing | 790 | Silicone-containing acrylate resin synthesized from silicone |
| | acrylate resin 6 | | resin KC-89 (manufactured by Shin-Etsu Chemical Co., Ltd.) |
| | | | and 2-hydroxyethyl acrylate |
| A-7 | Non-silicone 1 | 20000 | Dendrimer-type polyfunctional acrylate SIRIUS-501 (OSAKA |
| | | | ORGANIC CHEMICAL INDUSTRY LTD.) |
| A-8 | Non-silicone 2 | 1026 | 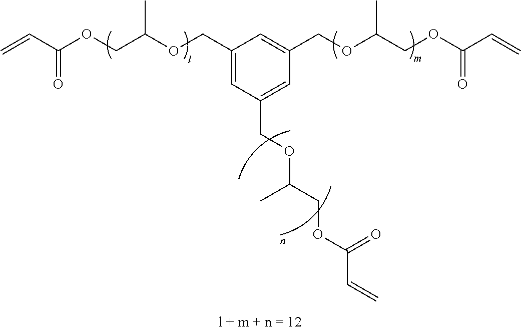 |
| A-9 | Difunctional acrylate 1 | 1216 | 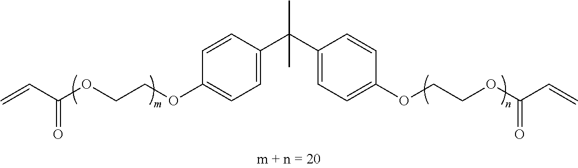 |
| A-10 | Difunctional acrylate 2 | 512 | 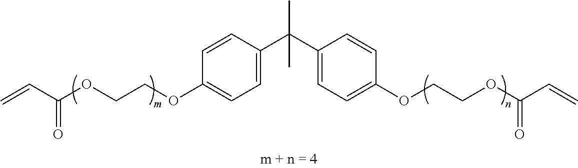 |
| A-11 | Difunctional acrylate 3 | 544 | 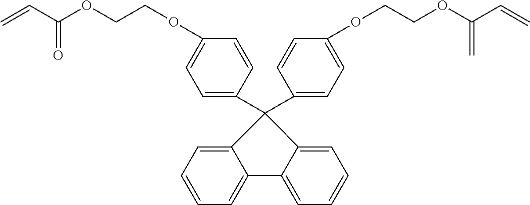 [SMILES: C=CC(=C)OCCOc1ccc(C2(c3ccc(OCCOC(=O)C=C)cc3)c3ccccc3-c3ccccc32)cc1] |

[Synthesis of A-1 (Silicone-Containing Acrylate Resin 1)]

A silicone resin X-40-9225 (trade name, manufactured by Shin-Etsu Chemical Co., Ltd.) (10 parts), 2-hydroxyethyl acrylate (58.1 parts), and paratoluene sulfonic acid monohydrate (0.034 parts) were mixed with each other, and then the mixture was heated at 120° C. and stirred for 3 hours while distilling off methanol produced by a condensation reaction to obtain 48 parts of A-1.

In addition, A-2 to A-6 were synthesized by the same method as A-1, except that the raw materials were appropriately changed.

TABLE 4

| Classification | Structural formula |
|---|---|
| B-1 | 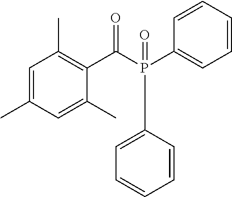 [SMILES: Cc1cc(C)c(C(=O)P(=O)(c2ccccc2)c2ccccc2)c(C)c1] |
| B-2 | 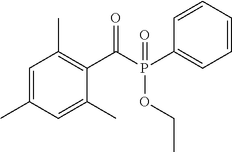 [SMILES: CCOP(=O)(C(=O)c1c(C)cc(C)cc1C)c1ccccc1] |
| B-3 | 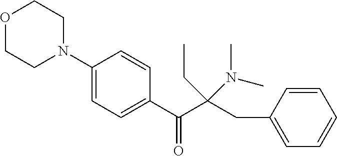 [SMILES: CCC(Cc1ccccc1)(C(=O)c1ccc(N2CCOCC2)cc1)N(C)C] |
| B-4 | 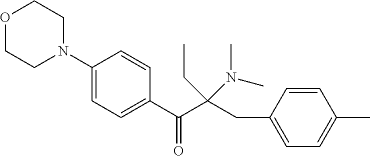 [SMILES: CCC(Cc1ccc(C)cc1)(C(=O)c1ccc(N2CCOCC2)cc1)N(C)C] |
| B-5 | 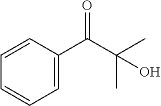 |
| B-6 | 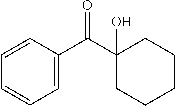 [SMILES: O=C(c1ccccc1)C1(O)CCCCC1] |
| B-7 | 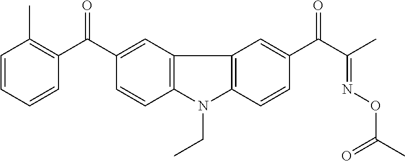 [SMILES: CCn1c2ccc(C(=O)/C(C)=N/OC(C)=O)cc2c2cc(C(=O)c3ccccc3C)ccc21] |
| B-8 | 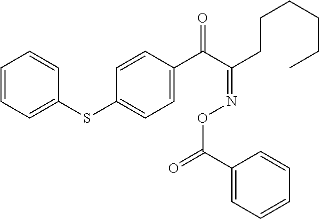 [SMILES: CCCCCC/C(=N/OC(=O)c1ccccc1)C(=O)c1ccc(Sc2ccccc2)cc1] |

TABLE 5

| Classification | Name | Structural formula |
|---|---|---|
| Z-1 | Ethyl 2,4,6- Trimethylbenzoate | 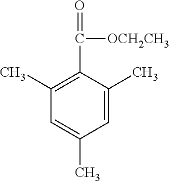 |
| Z-2 | tert-Butyl Phenyl ketone | 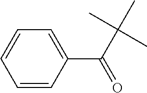 |

[Formation of Underlayer Film (Closely Adhesive Layer)]

In each of Examples and Comparative Examples, a composition for forming a closely adhesive layer, described in Example 6 of JP2014-024322A, was spin-coated on a silicon wafer, and heated for 1 minute using a hot plate at 250° C. to form an underlayer film (closely adhesive layer) having a thickness of 5 nm.

[Evaluation of Defects of Coating Film Over Time]

The above-described composition for forming an imprint pattern was spin-coated on the silicon wafer (silicon substrate), and heated using a hot plate at 80° C. to form a coating film of the composition for forming an imprint pattern on the silicon wafer. The thickness of the above-described coating film was the thickness (μm) described in the column of “Film thickness” in Table 1 or Table 2. The silicon wafer on which the above-described coating film had been formed was allowed to stand in air for 24 hours in a clean room of class 100, 23° C., and a humidity of 50%, and then observed with an optical microscope, and the number of defects having a maximum diameter of 100 μm or greater was counted. The number of defects per 1 cm² was calculated and evaluated according to the following evaluation standard. The evaluation results are described in the column of “Film stability”.

—Evaluation Standard—
A: no defect was observed in the coating film.
B: density of defects in the coating film was 1 piece/cm² or lower.
C: density of defects in the coating film was greater than 1 piece/cm² and lower than 5 pieces/cm².
D: density of defects in the coating film was 5 pieces/cm² or greater.

From the above results, it was found that, in a case where a coating film was formed of the composition for forming an imprint pattern according to the embodiment of the present invention, defects were less likely to occur in the obtained coating film even after 24 hours.

The composition according to Comparative Example 1 contained only one polymerization initiator and did not contain a derivative thereof. In such an aspect, it was found that the defects occurred in the coating film after 24 hours.

The composition according to Comparative Example 2 contained two kinds of the polymerization initiators, but one of them was not a derivative of the other. In addition, the composition according to Comparative Example 2 did not correspond to any aspect of including two or more kinds of oxime compounds, including two or more kinds of acylphosphine compounds, or including two or more kinds of alkylphenone compounds. In such an aspect, it was found that the defects occurred in the coating film after 24 hours.

Moreover, by the same method as the method of forming the closely adhesive layer described in the evaluation of defects of the coating film over time, the closely adhesive layer was formed on a silicon wafer using the composition for forming a closely adhesive layer, and a line & space structure, a contact hole structure, a dual damascene structure, and a staircase structure were formed on the closely adhesive layer of this silicon wafer with the closely adhesive layer using the composition for forming an imprint pattern according to each Example. In addition, each silicon wafer was dry-etched by using this pattern as an etching mask, and each semiconductor element was manufactured using this silicon wafer. There was no problem with the performance of any of the semiconductor elements. Further, using the above-described composition for forming a closely adhesive layer and the composition for forming an imprint pattern according to each Example, a semiconductor element was manufactured on a substrate having a spin-on carbon (SOC) layer by the same procedure as described above. There was no problem with the performance of this semiconductor element as well.

What is claimed is:

1. A composition for forming an imprint pattern, comprising:
a polymerizable compound;
a polymerization initiator; and
a derivative of the polymerization initiator.

2. The composition for forming an imprint pattern according to claim 1,
wherein a content of the derivative is 1 to 10,000 parts by mass in a case where a content of the polymerization initiator is set to 100 parts by mass.

3. The composition for forming an imprint pattern according to claim 1,
wherein a total content of the polymerization initiator and the derivative is 0.1 to 10.0 parts by mass in a case where a total solid content of the composition for forming an imprint pattern is set to 100 parts by mass.

4. The composition for forming an imprint pattern according to claim 1,
wherein the polymerization initiator is a photopolymerization initiator.

5. The composition for forming an imprint pattern according to claim 1,
wherein both the polymerization initiator and the derivative are acylphosphine oxide-based polymerization initiators or alkylphenone-based polymerization initiators.

6. The composition for forming an imprint pattern according to claim 1,
wherein one of the polymerization initiator or the derivative is diphenyl(2,4,6-trimethylbenzoyl)phosphine oxide and the other is ethyl phenyl(2,4,6-trimethylbenzoyl)phosphinate.

7. The composition for forming an imprint pattern according to claim 1,
wherein one of the polymerization initiator or the derivative is 2-benzyl-2-(dimethylamino)-4′-morpholinobutyrophenone and the other is 2-(dimethylamino)-2-(4-methylbenzyl)-1-(4-morpholinophenyl)butan-1-one.

8. The composition for forming an imprint pattern according to claim 1,
wherein one of the polymerization initiator or the derivative is 2-hydroxy-2-methylpropiophenone and the other is 1-hydroxycyclohexyl phenyl ketone.

9. A composition for forming an imprint pattern, comprising:
a polymerizable compound; and
a polymerization initiator,
wherein the polymerization initiator includes two or more kinds of oxime compounds, two or more kinds of acylphosphine compounds, or two or more kinds of alkylphenone compounds.

10. The composition for forming an imprint pattern according to claim 1, further comprising:
a mold release agent.

11. The composition for forming an imprint pattern according to claim 1, further comprising:
a solvent,
wherein a content of the solvent is 90.0% to 99.0% by mass with respect to a total mass of the composition for forming an imprint pattern.

12. A cured substance obtained by curing the composition for forming an imprint pattern according to claim 1.

13. An imprint pattern producing method comprising:
an applying step of applying the composition for forming an imprint pattern according to claim 1 onto a member to be applied, which is selected from the group consisting of a support and a mold;
a contact step of contacting a member which is not selected as the member to be applied from the group consisting of the support and the mold with the composition for forming an imprint pattern as a contact member;
a curing step of forming the composition for forming an imprint pattern into a cured substance; and
a peeling step of peeling off the mold from the cured substance.

14. The imprint pattern producing method according to claim 13,
wherein the support is a member including a closely adhesive layer on a surface on a side to which the composition for forming an imprint pattern is applied.

15. A method for manufacturing a device, comprising:
the imprint pattern producing method according to claim 13.

16. A device comprising:
the cured substance according to claim 12.
